(19) United States
(12) Patent Application Publication
(10) Pub. No.: US 2012/0294459 A1
(43) Pub. Date: Nov. 22, 2012

(54) Audio System and Method of Using Adaptive Intelligence to Distinguish Information Content of Audio Signals in Consumer Audio and Control Signal Processing Function

(75) Inventors: Keith L. Chapman, Fountain Hills, AZ (US); Stanley J. Cotey, Mesa, AZ (US); Zhiyun Kuang, Gilbert, AZ (US)

(73) Assignee: FENDER MUSICAL INSTRUMENTS CORPORATION, Scottsdale, AZ (US)

(21) Appl. No.: 13/189,414

(22) Filed: Jul. 22, 2011

Related U.S. Application Data
(63) Continuation-in-part of application No. 13/109,665, filed on May 17, 2011.

(51) Int. Cl. H03G 5/00

(52) U.S. Cl. 381/98

(57) ABSTRACT

A consumer audio system has a signal processor coupled for receiving an audio signal. The audio signal is sampled into a plurality of frames. The sampled audio frames are separated into sub-frames according to the type or frequency content of the sound generating source. A time domain processor generates time domain parameters from the separated sub-frames. A frequency domain processor generates frequency domain parameters from the separated sub-frames. The time domain processor or frequency domain processor can detects onset of a note of the audio signal. A signature database has signature records each having time domain parameters and frequency domain parameters and control parameters. A recognition detector matches the time domain parameters and frequency domain parameters of the separated sub-frames to a signature record of the signature database. The control parameters of the matching signature record control operation of the signal processor.

### CLAIM TO DOMESTIC PRIORITY

The present application is a continuation-in-part of U.S. patent application Ser. No. 13/109,665, filed May 17, 2011, and claims priority to the foregoing parent application pursuant to 35 U.S.C. §120.

### FIELD OF THE INVENTION

The present invention relates in general to audio systems and, more particularly, to an audio system and method of using adaptive intelligence to distinguish dynamic content of an audio signal generated by consumer audio and control a signal process function associated with the audio signal.

### BACKGROUND OF THE INVENTION

Audio sound systems are commonly used to amplify signals and reproduce audible sound. A sound generation source, such as a cellular telephone, mobile sound system, multi-media player, home entertainment system, internet streaming, computer, notebook, video gaming, or other electronic device, generates an electrical audio signal. The audio signal is routed to an audio amplifier, which controls the magnitude and performs other signal processing on the audio signal. The audio amplifier can perform filtering, modulation, distortion enhancement or reduction, sound effects, and other signal processing functions to enhance the tonal quality and frequency properties of the audio signal. The amplified audio signal is sent to a speaker to convert the electrical signal to audible sound and reproduce the sound generation source with enhancements introduced by the signal processing function.

In one example, the sound generation source may be a mobile sound system. The mobile sound system receives wireless audio signals from a transmitter or satellite, or recorded sound signals from compact disk (CD), memory drive, audio tape, or internal memory of the mobile sound system. The audio signals are routed to an audio amplifier. The audio amplifier provides features such as amplification, filtering, tone equalization, and sound effects. The user adjusts the knobs on the front panel of the audio amplifier to dial-in the desired volume, acoustics, and sound effects. The output of the audio amplifier is connected to a speaker to generate the audible sounds. In some cases, the audio amplifier and speaker are separate units. In other systems, the units are integrated into one chassis.

In audio reproduction, it is common to use a variety of signal processing techniques depending on the content of the audio signal to achieve better sound quality and otherwise enhance the listener's enjoyment and appreciation of the audio content. For example, the listener can adjust the audio amplifier settings and sound effects for different music styles. The audio amplifier can use different compressors and equalization settings to enhance sound quality, e.g., to optimize the reproduction of classical, pop, or rock music.

Audio amplifiers and other signal processing equipment are typically controlled with front panel switches and control knobs. To accommodate the processing requirements for different audio content, the user listens and manually selects the desired functions, such as amplification, filtering, tone equalization, and sound effects, by setting the switch positions and turning the control knobs. When the audio content changes, the user must manually make adjustments to the audio amplifier or other signal processing equipment to maintain an optimal sound reproduction of the audio signal. In some digital or analog audio sound systems, the user can configure and save preferred settings as presets and then later manually select the saved settings or factory presets for the system.

In most if not all cases, there is an inherent delay between changes in the audio content from sound generation source and optimal reproduction of the sound due to the time required for the user to make manual adjustments to the audio amplifier or other signal processing equipment. If the audio content changes from one composition to another, or even during playback of a single composition, and the user wants to change the signal processing function, e.g., increase volume or add more bass, then the user must manually change the audio amplifier settings. Frequent manual adjustments to the audio amplifier are typically required to maintain optimal sound reproduction over the course of multiple musical compositions or even within a single composition. Most users quickly tire of constantly making manual adjustments to the audio amplifier settings in an attempt to keep up with the changing audio content. The audio amplifier is rarely optimized to the audio content either because the user gives up making manual adjustments, or because the user cannot make adjustments quickly enough to track the changing audio content.

### SUMMARY OF THE INVENTION

A need exists to dynamically control an audio amplifier or other signal processing equipment in realtime. Accordingly, in one embodiment, the present invention is a consumer audio system comprising a signal processor coupled for receiving an audio signal from a consumer audio source. The dynamic content of the audio signal controls operation of the signal processor.

In another embodiment, the present invention is a method of controlling a consumer audio system comprising the steps of providing a signal processor adapted for receiving an audio signal from a consumer audio source, and controlling operation of the signal processor using dynamic content of the audio signal.

In another embodiment, the present invention is a consumer audio system comprising a signal processor coupled for receiving an audio signal from a consumer audio source. A time domain processor is coupled for receiving the audio signal and generating time domain parameters of the audio signal. A frequency domain processor is coupled for receiving the audio signal and generating frequency domain parameters of the audio signal. A signature database includes a plurality of signature records each having time domain parameters and frequency domain parameters and control parameters. A recognition detector matching the time domain parameters and frequency domain parameters of the audio signal to a signature record of the signature database. The control parameters of the matching signature record control operation of the signal processor.

In another embodiment, the present invention is a method of controlling a consumer audio system comprising the steps of providing a signal processor adapted for receiving an audio signal from a consumer audio source, generating time domain parameters of the audio signal, generating frequency domain parameters of the audio signal, providing a signature database including a plurality of signature records each having time domain parameters and frequency domain parameters and control parameters, matching the time domain parameters and frequency domain parameters of the audio signal to a signature record of the signature database, and controlling operation of the signal processor based on the control parameters of the matching signature record.

### BRIEF DESCRIPTION OF THE DRAWINGS

FIG. 1 illustrates an audio sound source generating an audio signal and routing the audio signal through signal processing equipment to a speaker;

FIG. 2 illustrates an automobile with an audio sound system connected to a speaker;

FIG. 3 illustrates further detail of the automobile sound system with an audio amplifier connected to a speaker;

FIG. 4a-4b illustrate musical instruments and vocals connected to a recording device;

FIGS. 5a-5b illustrate waveform plots of the audio signal;

FIG. 6 illustrates a block diagram of the audio amplifier with adaptive intelligence control;

FIG. 7 illustrates a block diagram of the frequency domain and time domain analysis block;

FIGS. 8a-8b illustrate time sequence frames of the sampled audio signal;

FIG. 9 illustrates the separated time sequence sub-frames of the audio signal;

FIG. 10 illustrates a block diagram of the time domain analysis block;

FIG. 11 illustrates a block diagram of the time domain energy level isolation block in frequency bands;

FIG. 12 illustrates a block diagram of the time domain note detector block;

FIG. 13 illustrates a block diagram of the time domain attack detector;

FIG. 14 illustrates another embodiment of the time domain attack detector;

FIG. 15 illustrates a block diagram of the frequency domain analysis block;

FIG. 16 illustrates a block diagram of the frequency domain note detector block;

FIG. 17 illustrates a block diagram of the energy level isolation in frequency bins;

FIG. 18 illustrates a block diagram of the frequency domain attack detector;

FIG. 19 illustrates another embodiment of the frequency domain attack detector;

FIG. 20 illustrates the frame signature database with parameter values, weighting values, and control parameters;

FIG. 21 illustrates a computer interface to the frame signature database;

FIG. 22 illustrates a recognition detector for the runtime matrix and frame signature database;

FIG. 23 illustrates a cellular phone having an audio amplifier with the adaptive intelligence control;

FIG. 24 illustrates a home entertainment system having an audio amplifier with the adaptive intelligence control; and

FIG. 25 illustrates a computer having an audio amplifier with the adaptive intelligence control.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

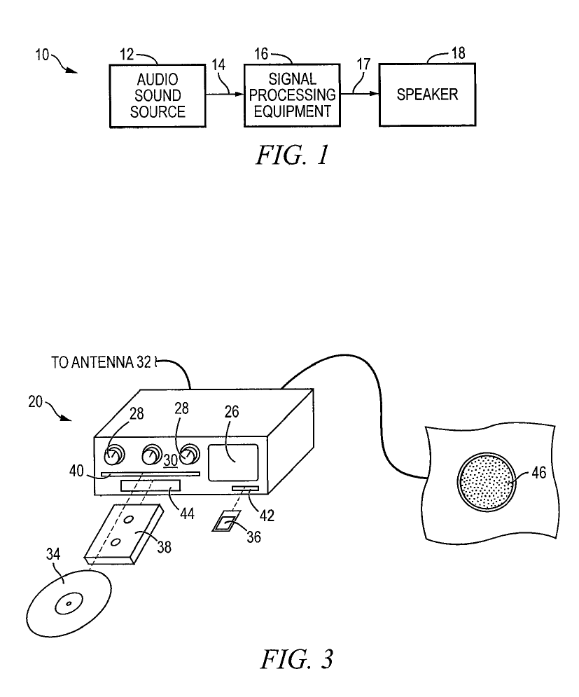

Referring to FIG. 1, an audio sound system 10 includes an audio sound source 12 which provides electric signals representative of sound content. Audio sound source 12 can be an antenna receiving audio signals from a transmitter or satellite. Alternatively, audio sound source 12 can be a compact disk (CD), memory drive, audio tape, or internal memory of a cellular telephone, mobile sound system, multi-media player, home entertainment system, computer, notebook, internet streaming, video gaming, or other consumer electronic device capable of playback of sound content. The electrical signals from audio sound source 12 are routed through audio cable 14 to signal processing equipment 16 for signal conditioning and power amplification. Signal processing equipment 16 can be an audio amplifier, cellular telephone, home theater system, computer, audio rack, or other consumer equipment capable of performing signal processing functions on the audio signal. The signal processing function can include amplification, filtering, equalization, sound effects, and user-defined modules that adjust the power level and enhance the signal properties of the audio signal. The signal conditioned audio signal is routed through audio cable 17 to speaker 18 to reproduce the sound content of audio sound source 12 with the enhancements introduced into the audio signal by signal processing equipment 16.

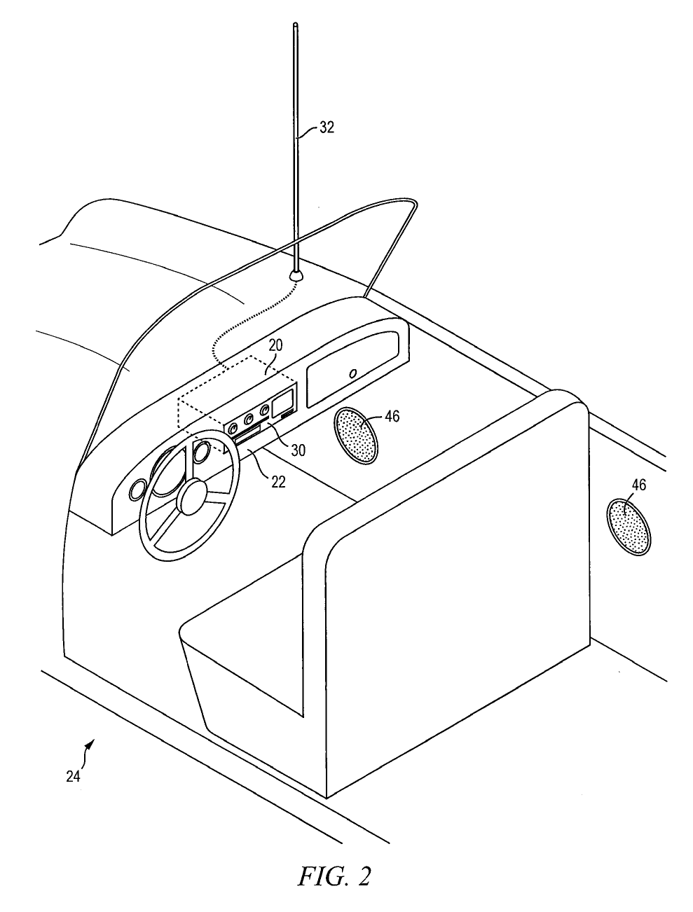

FIG. 2 shows a mobile sound system as audio sound source 12, in this case automobile sound system 20 mounted within dashboard 22 of automobile 24. The mobile sound system can be mounted within any land-based vehicle, marine, or aircraft. The mobile sound system can also be a handheld unit, e.g., MP3 player, cellular telephone, or other portable audio player. The user can manually operate automobile sound system 20 via visual display 26 and control knobs, switches, and rotary dials 28 located on front control panel 30 to select between different sources of the audio signal, as shown in FIG. 3. For example, automobile sound system 20 receives wireless audio signals from a transmitter or satellite through antenna 32. Alternatively, digitally recorded audio signals can be stored on CD 34, memory drive 36, or audio tape 38 and inserted into slots 40, 42, and 44 of automobile sound system 20 for playback. The digitally recorded audio signals can be stored in internal memory of automobile sound system 20 for playback.

For a given sound source, the user can use front control panel 30 to manually select between a variety of signal processing functions, such as amplification, filtering, equalization, sound effects, and user-defined modules that enhance the signal properties of the audio signal. Front control panel 30 can be fully programmable, menu driven, and use software to configure and control the sound reproduction features with visual display 26 and control knobs, switches, and rotary dials 28. The combination of visual display 26 and control knobs, switches, and dials 28 located on front control panel 30 provide control for the user interface over the different operational modes, access to menus for selecting and editing functions, and configuration of automobile sound system 20. The audio signals are routed to an audio amplifier within automobile sound system 20. The signal conditioned audio signal is routed to one or more speakers 46 mounted within automobile 24. The power amplification increases or decreases the power level and signal strength of the audio signal to drive the speaker and reproduce the sound content with the enhancements introduced into the audio signal by the audio amplifier.

In audio reproduction, it is common to use a variety of signal processing techniques depending on the content of the audio source, e.g., performance or playing style, to achieve better sound quality and otherwise enhance the listener's enjoyment and appreciation of the audio content. For example, the audio amplifier can use different compressors and equalization settings to enhance sound quality, e.g., to optimize the reproduction of classical or rock music.

Automobile sound system 20 receives audio signals from audio sound source 12, e.g., antenna 32, CD 34, memory drive 36, audio tape 38, or internal memory. The audio signal can originate from a variety of audio sources, such as musical instruments or vocals which are recorded and transmitted to automobile sound system 20, or digitally recorded on CD 34, memory drive 36, or audio tape 38 and inserted into slots 40, 42, and 44 of automobile sound system 20 for playback. The digitally recorded audio signal can be stored in internal memory of automobile sound system 20. The instrument can be an electric guitar, bass guitar, violin, horn, brass, drums, wind instrument, piano, electric keyboard, or percussions. The audio signal can originate from an audio microphone handled by a male or female with voice ranges including soprano, mezzo-soprano, contralto, tenor, baritone, and bass. In many cases, the audio sound signal contains sound content associated with a combination of instruments, e.g., guitar, drums, piano, and voice, mixed together according to the melody and lyrics of the composition. Many compositions contain multiple instruments and multiple vocal components.

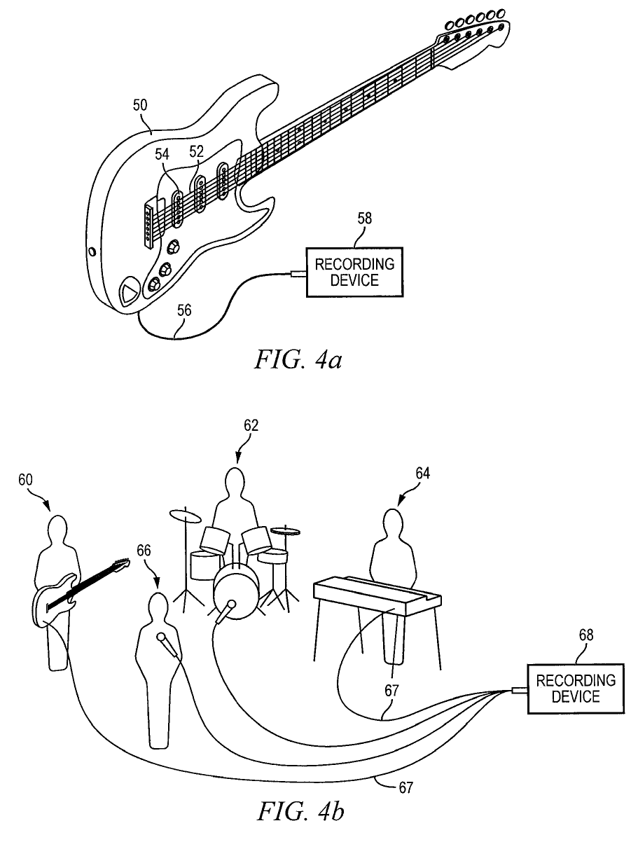

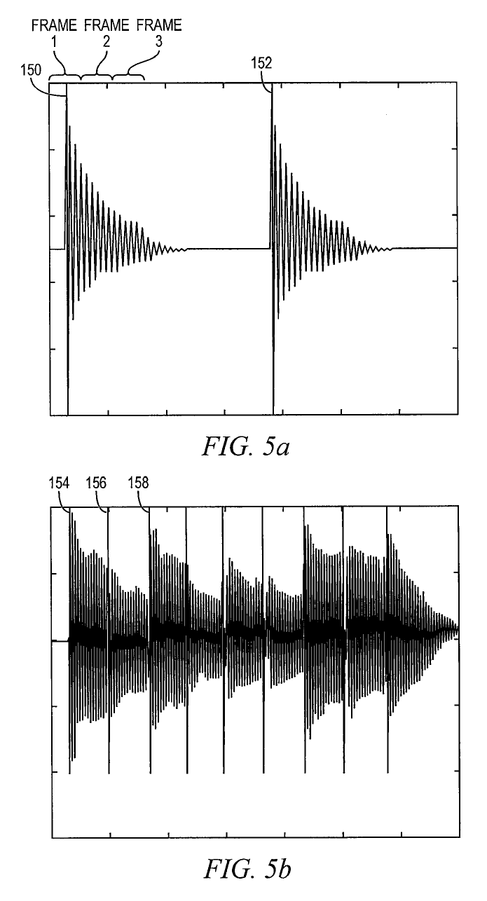

In one example, the audio signal contains in part sound originally created by electric bass guitar 50, as shown in FIG. 4a. When exciting strings 52 of bass guitar 50 with the musician's finger or guitar pick, the string begins a strong vibration or oscillation that is detected by pickup 54. The string vibration attenuates over time and returns to a stationary state, assuming the string is not excited again before the vibration ceases. The initial excitation of strings 52 is known as the attack phase. The attack phase is followed by a sustain phase during which the string vibration remains relatively strong. A decay phase follows the sustain phase as the string vibration attenuates and finally a release phase as the string returns to a stationary state. Pickup 54 converts string oscillations during the attack phase, sustain phase, decay phase, and release phase to an electrical signal, i.e., the analog audio signal, having an initial and then decaying amplitude at a fundamental frequency and harmonics of the fundamental. FIGS. 5a-5b illustrate amplitude responses of the audio signal in time domain corresponding to the attack phase and sustain phase and, depending on the figure, the decay phase and release phase of strings in various playing modes. In FIG. 5b, the next attack phase begins before completing the previous decay phase or even beginning the release phase.

The artist can use a variety of playing styles when playing bass guitar 50. For example, the artist can place his or her hand near the neck pickup or bridge pickup and excite strings 52 with a finger pluck, known as “fingering style”, for modern pop, rhythm and blues, and avant-garde styles. The artist can slap strings 52 with the fingers or palm, known as “slap style”, for modern jazz, funk, rhythm and blues, and rock styles. The artist can excite strings 52 with the thumb, known as “thumb style”, for Motown rhythm and blues. The artist can tap strings 52 with two hands, each hand fretting notes, known as “tapping style”, for avant-garde and modern jazz styles. In other playing styles, artists are known to use fingering accessories such as a pick or stick. In each case, strings 52 vibrate with a particular amplitude and frequency and generate a unique audio signal in accordance with the string vibrations phases, such as shown in FIGS. 5a and 5b.

The audio signal from bass guitar 50 is routed through audio cable 56 to recording device 58. Recording device 58 stores the audio signal in digital or analog format on CD 34, memory drive 36, or audio tape 38 for playback on automobile sound system 20. Alternatively, the audio signal is stored on recording device 58 for transmission to automobile sound system 20 via antenna 32. The audio signal generated by guitar 50 and stored in recording device 58 is shown by way of example. In many cases, the audio signal contains sound content associated with a combination of instruments, e.g., guitar 60, drums 62, piano 64, and voice 66, mixed together according to the melody and lyrics of the composition, e.g., by a band or orchestra, as shown in FIG. 4b. The composition can be classical, country, avant-garde, pop, jazz, rock, rhythm and blues, hip hop, or easy listening, just to name a few. The composite audio signal is routed through audio cable 67 and stored on recording device 68. Recording device 68 stores the composite audio signal in digital or analog format. The recorded composite audio signal is transferred to CD 34, memory drive 36, audio tape 38, or internal memory for playback on automobile sound system 20. Alternatively, the composite audio signal is stored on recording device 68 for transmission to automobile sound system 20 via antenna 32.

Returning to FIG. 3, the audio signal received from CD 34, memory drive 36, audio tape 38, antenna 32, or internal memory is processed through an audio amplifier in automobile sound system 20 for a variety of signal processing functions. The signal conditioned audio signal is routed to one or more speakers 46 mounted within automobile 24.

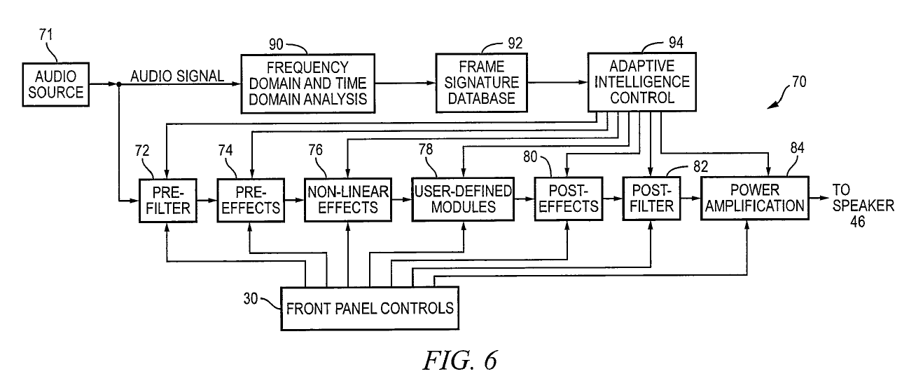

FIG. 6 is a block diagram of audio amplifier 70 contained within automobile sound system 20. Audio amplifier 70 performs amplification and other signal processing functions, such as equalization, filtering, sound effects, and user-defined modules, on the audio signal to adjust the power level and otherwise enhance the signal properties for the listening experience. Audio source block 71 represents antenna 32, CD 34, memory drive 36, audio tape 38, or internal memory automobile sound system 20 and provides the audio signal. Audio amplifier 70 has a signal processing path for the audio signal, including pre-filter block 72, pre-effects block 74, non-linear effects block 76, user-defined modules 78, post-effects block 80, post-filter block 82, and power amplification block 84. Pre-filtering block 72 and post-filtering block 82 provide various filtering functions, such as low-pass filtering and bandpass filtering of the audio signal. The pre-filtering and post-filtering can include tone equalization functions over various frequency ranges to boost or attenuate the levels of specific frequencies without affecting neighboring frequencies, such as bass frequency adjustment and treble frequency adjustment. For example, the tone equalization may employ shelving equalization to boost or attenuate all frequencies above or below a target or fundamental frequency, bell equalization to boost or attenuate a narrow range of frequencies around a target or fundamental frequency, graphic equalization, or parametric equalization. Pre-effects block 74 and post-effects block 80 introduce sound effects into the audio signal, such as reverb, delays, chorus, wah, auto-volume, phase shifter, hum canceller, noise gate, vibrato, pitch-shifting, tremolo, and dynamic compression. Non-linear effects block 76 introduces non-linear effects into the audio signal, such as m-modeling, distortion, overdrive, fuzz, and modulation. User-defined module block 78 allows the user to define customized signal processing functions, such as adding accompanying instruments, vocals, and synthesizer options. Power amplification block 84 provides power amplification or attenuation of the audio signal. The post signal processing audio signal is routed to speakers 46 in automobile 24.

The pre-filter block 72, pre-effects block 74, non-linear effects block 76, user-defined modules 78, post-effects block 80, post-filter block 82, and power amplification block 84 within audio amplifier 70 are selectable and controllable with front control panel 30 in FIG. 3. By viewing display 26 and turning control knobs, switches, and dials 28, the user can manually control operation of the signal processing functions within audio amplifier 70.

A feature of audio amplifier 70 is the ability to control the signal processing function in accordance with the dynamic content of the audio signal. Audio amplifier 70 employs a dynamic adaptive intelligence feature involving frequency domain analysis and time domain analysis of the audio signal on a frame-by-frame basis to automatically and adaptively control operation of the signal processing functions and settings within the audio amplifier to achieve an optimal sound reproduction. The dynamic adaptive intelligence feature of audio amplifier 70 detects and isolates the frequency domain characteristics and time domain characteristics of the audio signal on a frame-by-frame basis and uses that information to control operation of the signal processing function of the amplifier.

FIG. 6 further illustrates the dynamic adaptive intelligence control feature of audio amplifier 70 provided by frequency domain and time domain analysis block 90, frame signature block 92, and adaptive intelligence control block 94. The audio signal is routed to frequency domain and time domain analysis block 90 where the audio signal is sampled with an analog-to-digital (A/D) converter and arranged into a plurality of time progressive frames 1, 2, 3, . . . n, each containing a predetermined number of samples. Each sampled audio frame is separated into sub-frames according to the type of audio source or frequency content of the audio source. Each separated sub-frame of the audio signal is analyzed on a frame-by-frame basis to determine its time domain and frequency domain content and characteristics.

The output of block 90 is routed to frame signature block 92 where the incoming sub-frames of the audio signal are compared to a database of established or learned frame signatures to determine a best match or closest correlation of the incoming sub-frame to the database of frame signatures. The frame signatures from the database contain control parameters to configure the signal processing components of audio amplifier 70.

The output of block 92 is routed to adaptive intelligence control block 94 where the best matching frame signature controls audio amplifier 70 in realtime to continuously and automatically make adjustments to the signal processing functions for an optimal sound reproduction. For example, based on the frame signature, the amplification of the audio signal can be increased or decreased automatically for that particular sub-frame of the audio signal. Presets and sound effects can be engaged or removed automatically for the note being played. The next sub-frame in sequence may be associated with the same note and matches with the same frame signature in the database, or the next sub-frame in sequence may be associated with a different note and matches with a different corresponding frame signature in the database. Each sub-frame of the audio signal is recognized and matched to a frame signature that in turn controls operation of the signal processing function within audio amplifier 70 for optimal sound reproduction. The signal processing function of audio amplifier 70 is adjusted in accordance with the best matching frame signature corresponding to each individual incoming sub-frame of the audio signal to enhance its reproduction.

The adaptive intelligence feature of audio amplifier 70 can learn attributes of each note of the audio signal and make adjustments based on user feedback. For example, if the user desires more or less amplification or equalization, or insertion of a particular sound effect for a given note, then audio amplifier builds those user preferences into the control parameters of the signal processing function to achieve the optimal sound reproduction. The database of frame signatures with correlated control parameters makes realtime adjustments to the signal processing function. The user can define audio modules, effects, and settings which are integrated into the database of audio amplifier 70. With adaptive intelligence, audio amplifier 70 can detect and automatically apply tone modules and settings to the audio signal based on the present frame signature. Audio amplifier 70 can interpolate between similar matching frame signatures as necessary to select the best choice for the instant signal processing function.

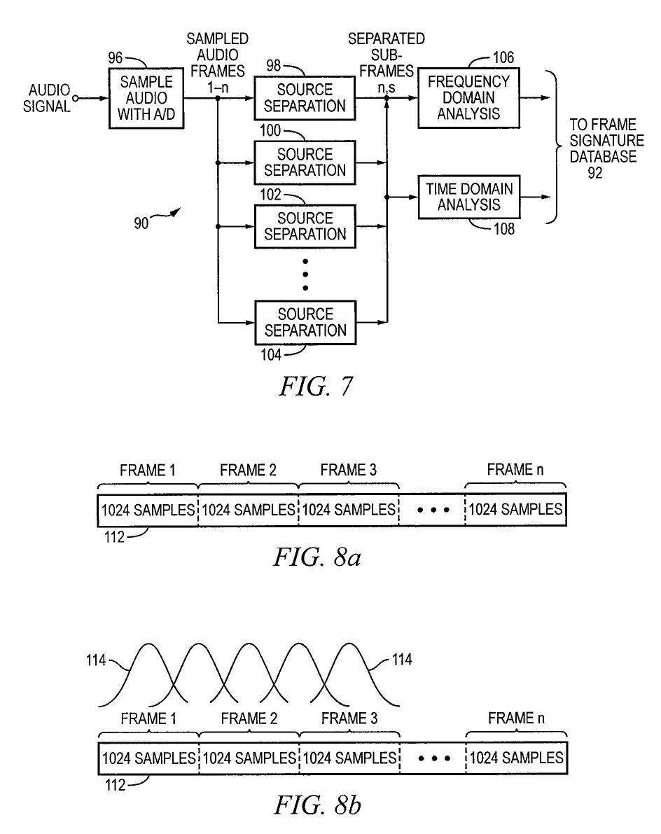

FIG. 7 illustrates further detail of frequency domain and time domain analysis block 90, including sample audio block 96, source separation blocks 98-104, frequency domain analysis block 106, and time domain analysis block 108. The analog audio signal is presented to sample audio block 96. The sampled audio block 96 samples the analog audio signal, e.g., 32 to 1024 samples per second, using an A/D converter. The sampled audio signal 112 is organized into a series of time progressive frames (frame 1 to frame n) each containing a predetermined number of samples of the audio signal. FIG. 8a shows frame 1 containing 1024 samples of audio signal 112 in time sequence, frame 2 containing the next 1024 samples of audio signal 112 in time sequence, frame 3 containing the next 1024 samples of audio signal 112 in time sequence, and so on through frame n containing 1024 samples of audio signal 112 in time sequence. FIG. 8b shows overlapping windows 114 of frames 1-n used in time domain to frequency domain conversion, as described in FIG. 15.

The sampled audio signal 112 is routed to source separation blocks 98-104 to isolate sound components associated with specific types of sound sources. The source separation blocks 98-104 separate the sampled audio signal 112 into sub-frames n,s, where n is the frame number and s is the separated sub-frame number. Assume the sampled audio signal includes sound components associated with a variety of instruments and vocals. For example, audio sound block 71 provides an audio signal containing sound components from guitar 60, drums 62, piano 64, and vocals 66, see FIG. 4b. Source separation block 98 is configured to identify and isolate sound components associated with guitar 60. The source separation 98 identifies frequency characteristics associated with guitar 60 and separates those sound components with the sampled audio signal 112. The frequency characteristics of guitar 60 can be isolated and identified by analyzing its amplitude and frequency content, e.g., with a bandpass filter. The output of source separation block 98 is separated sub-frame n,1 containing the isolated sound content associated with guitar 60. In a similar manner, source separation block 100 is configured to identify and isolate sound components associated with drums 62. The output of source separation block 100 is separated sub-frame n,2 containing the isolated sound content associated with drums 62. Source separation block 102 is configured to identify and isolate sound components associated with piano 64. The output of source separation block 102 is separated sub-frame n,3 containing the isolated sound content associated with piano 64. Source separation block 104 is configured to identify and isolate sound components associated with vocals 66. The output of source separation block 104 is separated sub-frame n,s containing the isolated sound content associated with vocals 66.

In another embodiment, source separation block 98 identifies sound content within a particular frequency band 1, e.g., 100-500 Hz, and separates the sampled audio signal 112 according to frequency content within frequency band 1. The sound content of the sampled audio signal 112 can be isolated and identified by analyzing its amplitude and frequency content, e.g., with a bandpass filter. The output of source separation block 98 is separated sub-frame n,1 containing the isolated frequency content within frequency band 1. In a similar manner, source separation block 100 identifies frequency characteristics associated with frequency band 2, e.g., 500-1000 Hz, and separates the sampled audio signal 112 according to frequency content within frequency band 2. The output of source separation block 100 is separated sub-frame n,2 containing the isolated frequency content within frequency band 2. Source separation block 102 identifies frequency characteristics associated with frequency band 3, e.g., 1000-1500 Hz, and separates the sampled audio signal 112 according to frequency content within frequency band 3. The output of source separation block 102 is separated sub-frame n,3 containing the isolated frequency content within frequency band 3. Source separation block 104 identifies frequency characteristics associated with frequency band 4, e.g., 1500-2000 Hz, and separates the sampled audio signal 112 according to frequency content within frequency band 4. The output of source separation block 104 is separated sub-frame n,4 containing the isolated frequency content within frequency band 4.

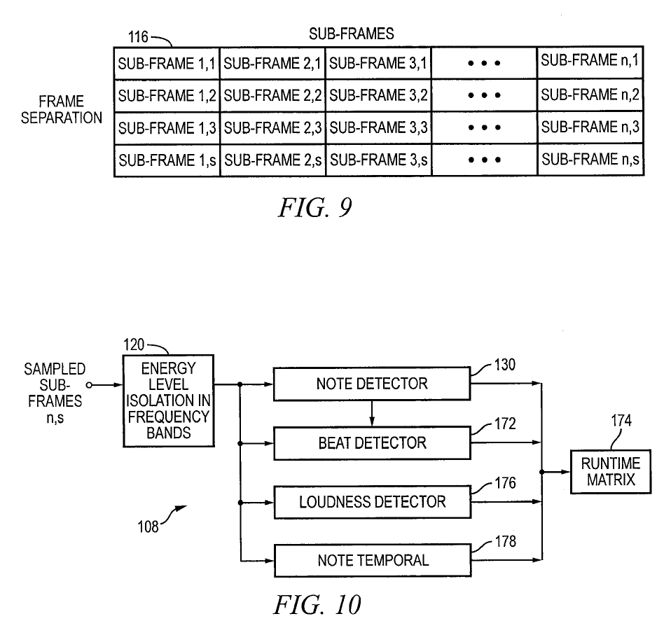

FIG. 9 illustrates the outputs of source separation blocks 98-104 as source separated sub-frames 116. The source separated sub-frames 116 are designated by separated sub-frame n,s, where n is the frame number and s is the separated sub-frame number. The separated sub-frame 1,1 is the sound content of guitar 60 or frequency content of frequency band 1 in frame 1 of FIG. 8a; separated sub-frame 2,1 is the sound content of guitar 60 or frequency content of frequency band 1 in frame 2; separated sub-frame 3,1 is the sound content of guitar 60 or frequency content of frequency band 1 in frame 3; separated sub-frame n,1 is the sound content of guitar 60 or frequency content of frequency band 1 in frame n. The separated sub-frame 1,2 is the sound content of drums 62 or frequency content of frequency band 2 in frame 1 of FIG. 8a; separated sub-frame 2,2 is the sound content of drums 62 or frequency content of frequency band 2 in frame 2; separated sub-frame 3,2 is the sound content of drums 62 or frequency content of frequency band 2 in frame 3; separated sub-frame n,2 is the sound content of drums 62 or frequency content of frequency band 2 in frame n. The separated sub-frame 1,3 is the sound content of piano 64 or frequency content of frequency band 3 in frame 1 of FIG. 8a; separated sub-frame 2,3 is the sound content of piano 64 or frequency content of frequency band 3 in frame 2; separated sub-frame 3,3 is the sound content of piano 64 or frequency content of frequency band 3 in frame 3; separated sub-frame n,3 is the sound content of piano 64 or frequency content of frequency band 3 in frame n. The separated sub-frame 1,s is the sound content of vocals 66 or frequency content of frequency band 4 in frame 1 of FIG. 8a; separated sub-frame 2,s is the sound content of vocals 66 or frequency content of frequency band 4 in frame 2; separated sub-frame 3,s is the sound content of vocals 66 or frequency content of frequency band 4 in frame 3; separated sub-frame n,s is the sound content of vocals 66 or frequency content of frequency band 4 in frame n. The separated sub-frames n,s are routed to frequency domain analysis block 106 and time domain analysis block 108.

FIG. 10 illustrates further detail of time domain analysis block 108 including energy level isolation block 120 which isolates the energy level of each separated sub-frame n,s of the sampled audio signal 112 in multiple frequency bands. In FIG. 11, energy level isolation block 120 processes each separated sub-frame n,s in time sequence through filter frequency band 122a-122c to separate and isolate specific frequencies of the audio signal. The filter frequency bands 122a-122c can isolate specific frequency bands in the audio range of 100-10000 Hz. In one embodiment, filter frequency band 122a is a bandpass filter with a pass band centered at 100 Hz, filter frequency band 122b is a bandpass filter with a pass band centered at 500 Hz, and filter frequency band 122c is a bandpass filter with a pass band centered at 1000 Hz. The output of filter frequency band 122a contains the energy level of the separated sub-frame n,s centered at 100 Hz. The output of filter frequency band 122b contains the energy level of the separated sub-frame n,s centered at 500 Hz. The output of filter frequency band 122c contains the energy level of the separated sub-frame n,s centered at 1000 Hz. The output of other filter frequency bands each contain the energy level of the separated sub-frame n,s for a given specific band. Peak detector 124a monitors and stores peak energy levels of the separated sub-frame n,s centered at 100 Hz. Peak detector 124b monitors and stores the peak energy levels of the separated sub-frame n,s centered at 500 Hz. Peak detector 124c monitors and stores the peak energy levels of the separated sub-frame n,s centered at 1000 Hz. Smoothing filter 126a removes spurious components and otherwise stabilizes the peak energy levels of the separated sub-frame n,s centered at 100 Hz. Smoothing filter 126b removes spurious components and otherwise stabilizes the peak energy levels of the separated sub-frame n,s centered at 500 Hz. Smoothing filter 126c removes spurious components of the peak energy levels and otherwise stabilizes the separated sub-frame n,s centered at 1000 Hz. The output of smoothing filters 126a-126c is the energy level function E(m,n) for each separated sub-frame n,s in each frequency band 1-m.

The time domain analysis block 108 of FIG. 7 also includes note detector block 130, as shown in FIG. 10. Block 130 detects the onset of each note. Note detector block 130 associates the attack phase of strings 52 as the onset of a note. That is, the attack phase of the vibrating string 52 on guitar 50 or 60 coincides with the detection of a specific note. For other instruments, note detection is associated with a distinct physical act by the artist, e.g., pressing the key of a piano or electric keyboard, exciting the string of a harp, exhaling air into a horn while pressing one or more keys on the horn, or striking the face of a drum with a drumstick. In each case, note detector block 130 monitors the time domain dynamic content of the separated sub-frame n,s and identifies the onset of a note.

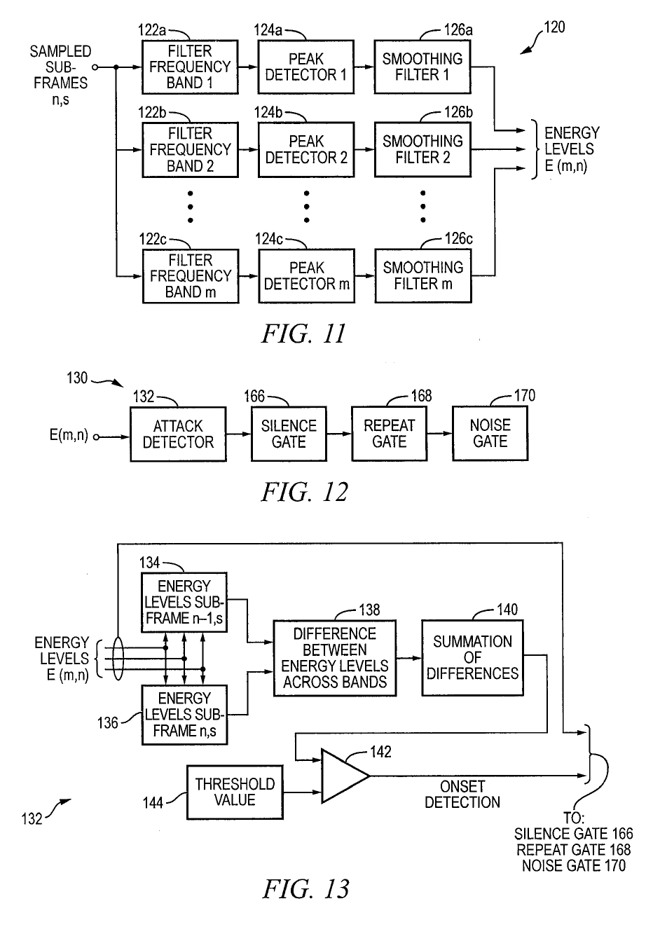

FIG. 12 shows further detail of note detector block 130 including attack detector 132. Once the energy level function E(m,n) is determined for each frequency band 1-m of the separated sub-frame n,s, the energy levels 1-m of one separated sub-frame n−1,s are stored in block 134 of attack detector 132, as shown in FIG. 13. The energy levels of frequency bands 1-m for the next separated sub-frame n,s, as determined by filter frequency bands 122a-122c, peak detectors 124a-124c, and smoothing filters 126a-126c, are stored in block 136 of attack detector 132. Difference block 138 determines a difference between energy levels of corresponding bands of the present separated sub-frame n,s and the previous separated sub-frame n−1,s. For example, the energy level of frequency band 1 for separated sub-frame n−1,s is subtracted from the energy level of frequency band 1 for separated sub-frame n,s. The energy level of frequency band 2 for separated sub-frame n−1,s is subtracted from the energy level of frequency band 2 for separated sub-frame n,s. The energy level of frequency band m for separated sub-frame n−1,s is subtracted from the energy level of frequency band m for separated sub-frame n,s. The difference in energy levels for each frequency band 1-m of separated sub-frame n−1,s and separated sub-frame n,s are summed in summer 140.

Summer 140 accumulates the difference in energy levels E(m,n) of each frequency band 1-m of separated sub-frame n−1,s and separated sub-frame n,s. The onset of a note will occur when the total of the differences in energy levels E(m,n) across the entire monitored frequency bands 1-m for the separated sub-frames n,s exceeds a predetermined threshold value. Comparator 142 compares the output of summer 140 to a threshold value 144. If the output of summer 140 is greater than threshold value 144, then the accumulation of differences in the energy levels E(m,n) over the entire frequency spectrum for the separated sub-frames n,s exceeds the threshold value 144 and the onset of a note is detected in the instant separated sub-frame n,s. If the output of summer 140 is less than threshold value 144, then no onset of a note is detected.

At the conclusion of each separated sub-frame n,s, attack detector 132 will have identified whether the instant separated sub-frame contains the onset of a note, or whether the instant separated sub-frame contains no onset of a note. For example, based on the summation of differences in energy levels E(m,n) of the separated sub-frames n,s over the entire spectrum of frequency bands 1-m exceeding threshold value 144, attack detector 132 may have identified separated sub-frame 1,s of FIG. 9 as containing the onset of a note, while separated sub-frame 2,s and separated sub-frame 3,s of FIG. 9 have no onset of a note. FIG. 5a illustrates the onset of a note at point 150 in separated sub-frame 1,s (based on the energy levels E(m,n) of the sampled audio signal within frequency bands 1-m) and no onset of a note in separated sub-frame 2,s or separated sub-frame 3,s. FIG. 5a has another onset detection of a note at point 152. FIG. 5b shows onset detections of a note at points 154, 156, and 158.

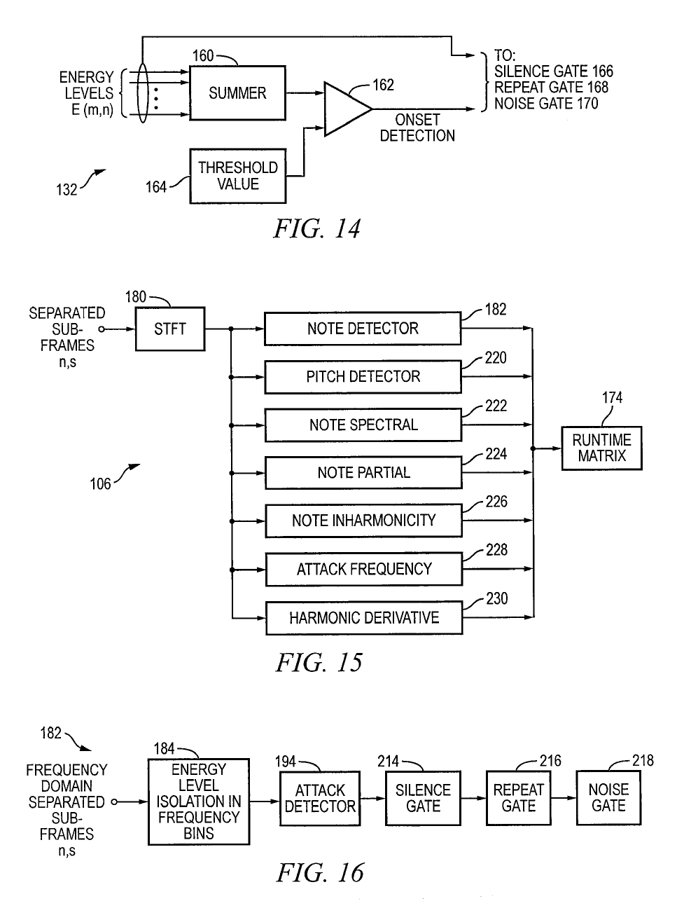

FIG. 14 illustrates another embodiment of attack detector 132 as directly summing the energy levels E(m,n) with summer 160. Summer 160 accumulates the energy levels E(m,n) of separated sub-frame n,s in each frequency band 1-m. The onset of a note will occur when the total of the energy levels E(m,n) across the entire monitored frequency bands 1-m for the separated sub-frames n,s exceeds a predetermined threshold value. Comparator 162 compares the output of summer 160 to a threshold value 164. If the output of summer 160 is greater than threshold value 164, then the accumulation of energy levels E(m,n) over the entire frequency spectrum for the separated sub-frames n,s exceeds the threshold value 164 and the onset of a note is detected in the instant separated sub-frame n,s. If the output of summer 160 is less than threshold value 164, then no onset of a note is detected.

At the conclusion of each frame, attack detector 132 will have identified whether the instant separated sub-frame contains the onset of a note, or whether the instant separated sub-frame contains no onset of a note. For example, based on the summation of energy levels E(m,n) of the separated sub-frames n,s within frequency bands 1-m exceeding threshold value 164, attack detector 132 may have identified separated sub-frame 1,s of FIG. 9 as containing the onset of a note, while separated sub-frame 2,s and separated sub-frame 3,s of FIG. 9 have no onset of a note.

Equation (1) provides another illustration of onset detection of a note.

g(m,n)=max(0,[E(m,n)/E(m,n−1)]−1) (1)

where:
g(m,n) is a maximum function of energy levels over
n separated sub-frames of m frequency bands
E(m,n) is the energy level of separated sub-frame n,s of frequency band m
E(m,n−1) is the energy level of separated sub-frame
n−1,s of frequency band m

The function g(m,n) has a value for each frequency band 1-m and each separated sub-frame n,s. If the ratio of E(m,n)/E(m,n−1), i.e., the energy level of band m in separated sub-frame n,s to the energy level of band m in separated sub-frame n−1,s, is less than one, then [E(m,n)/E(m,n−1)]−1 is negative. The energy level of band m in separated sub-frame n,s is not greater than the energy level of band m in separated sub-frame n−1,s. The function g(m,n) is zero indicating no initiation of the attack phase and therefore no detection of the onset of a note. If the ratio of E(m,n)/E(m,n−1), i.e., the energy level of band m in separated sub-frame n,s to the energy level of band m in separated sub-frame n−1,s, is greater than one (say value of two), then [E(m,n)/E(m,n−1)]−1 is positive, i.e., value of one. The energy level of band m in separated sub-frame n,s is greater than the energy level of band m in separated sub-frame n−1,s. The function g(m,n) is the positive value of [E(m,n)/E(m,n−1)]−1 indicating initiation of the attack phase and a possible detection of the onset of a note.

Returning to FIG. 12, attack detector 132 routes the onset detection of a note to silence gate 166, repeat gate 168, and noise gate 170. Not every onset detection of a note is genuine. Silence gate 166 monitors the energy levels E(m,n) of the separated sub-frame n,s after the onset detection of a note. If the energy levels E(m,n) of the separated sub-frame n,s after the onset detection of a note are low due to silence, e.g., −45 dB, then the energy levels E(m,n) of the separated sub-frame n,s that triggered the onset of a note are considered to be spurious and rejected. For example, the artist may have inadvertently touched one or more of strings 52 without intentionally playing a note or chord. The energy levels E(m,n) of the separated sub-frame n,s resulting from the inadvertent contact may have been sufficient to detect the onset of a note, but because playing does not continue, i.e., the energy levels E(m,n) of the separated sub-frame n,s after the onset detection of a note indicate silence, the onset detection is rejected.

Repeat gate 168 monitors the number of onset detections occurring within a time period. If multiple onsets of a note are detected within a repeat detection time period, e.g., 50 milliseconds (ms), then only the first onset detection is recorded. That is, any subsequent onset of a note that is detected, after the first onset detection, within the repeat detection time period is rejected.

Noise gate 170 monitors the energy levels E(m,n) of the separated sub-frame n,s about the onset detection of a note. If the energy levels E(m,n) of the separated sub-frame n,s about the onset detection of a note are generally in the low noise range, e.g., the energy levels E(m,n) are −90 dB, then the onset detection is considered suspect and rejected as unreliable. A valid onset detection of a note for the instant separated sub-frame n,s is stored in runtime matrix 174.

The time domain analysis block 108 of FIG. 7 also includes beat detector block 172, as shown in FIG. 10. Block 172 determines the number of note detections per unit of time, i.e., tempo of the composition. The onset detection of a note is determined by note detector 130. A number of note onset detections is record in a given time period. The number of note onset detections in a given time period is the beat. The beat detector is a time domain parameter or characteristic of each separated sub-frame n,s for all frequency bands 1-m and is stored as a value in runtime matrix 174 on a frame-by-frame basis.

Loudness detector block 176 uses the energy function E(m,n) to determine the power spectrum of the separated sub-frames n,s. The power spectrum can be an average or root mean square (RMS) of the energy function E(m,n) of the separated sub-frames n,s. The beat detector is a time domain parameter or characteristic of each separated sub-frame n,s for all frequency bands 1-m and is stored as a value in runtime matrix 174 on a frame-by-frame basis.

Note temporal block 178 determines time period of the attack phase, sustain phase, decay phase, and release phase of the separated sub-frames n,s. The note temporal is a time domain parameter or characteristic of each separated sub-frame n,s for all frequency bands 1-m and is stored as a value in runtime matrix 174 on a frame-by-frame basis.

The frequency domain analysis block 106 in FIG. 7 includes STFT block 180, as shown in FIG. 15. Block 180 performs a time domain to frequency domain conversion on a frame-by-frame basis of the separated sub-frames 116 using a constant overlap adds (COLA) short time Fourier transform (STFT) or other fast Fourier transform (FFT). The COLA STFT 180 performs time domain to frequency domain conversion using overlap analysis windows 114, as shown in FIG. 8b. The sampling windows 114 overlap by a predetermined number of samples of the audio signal, known as hop size, for additional sample points in the COLA STFT analysis to ensure that data is weighted equally in successive frames. Equation (2) provides a general format of the time domain to frequency domain conversion on the separated sub-frames 116.

$${X}_{m} ( k ) = {\sum }_{n = 0}^{N - 1} x ( n ) {e}^{- j 2 π \frac{k}{N} n} \qquad ( 2 )$$

where:
Xₙ is the audio signal in frequency domain
x(n) is the mth sub-frame of the audio input signal
m is the current number of sub-frame
k is the frequency bin
N is the STFT size

In another embodiment, block 180 performs a time domain to frequency domain conversion of the separated sub-frames 116 using an autoregressive function on a frame-by-frame basis.

The frequency domain analysis block 106 of FIG. 7 also includes note detector block 182, as shown in FIG. 15. Once the separated sub-frames 116 are in frequency domain, block 182 detects the onset of each note. Note detector block 182 associates the attack phase of string 52 as the onset of a note. That is, the attack phase of the vibrating string 52 on guitar 50 or 60 coincides with the detection of a specific note. For other instruments, note detection is associated with a distinct physical act by the artist, e.g., pressing the key of a piano or electric keyboard, exciting the string of a harp, exhaling air into a horn while pressing one or more keys on the horn, or striking the face of a drum with a drumstick. In each case, note detector block 182 monitors the frequency domain dynamic content of the separated sub-frames 116 and identifies the onset of a note.

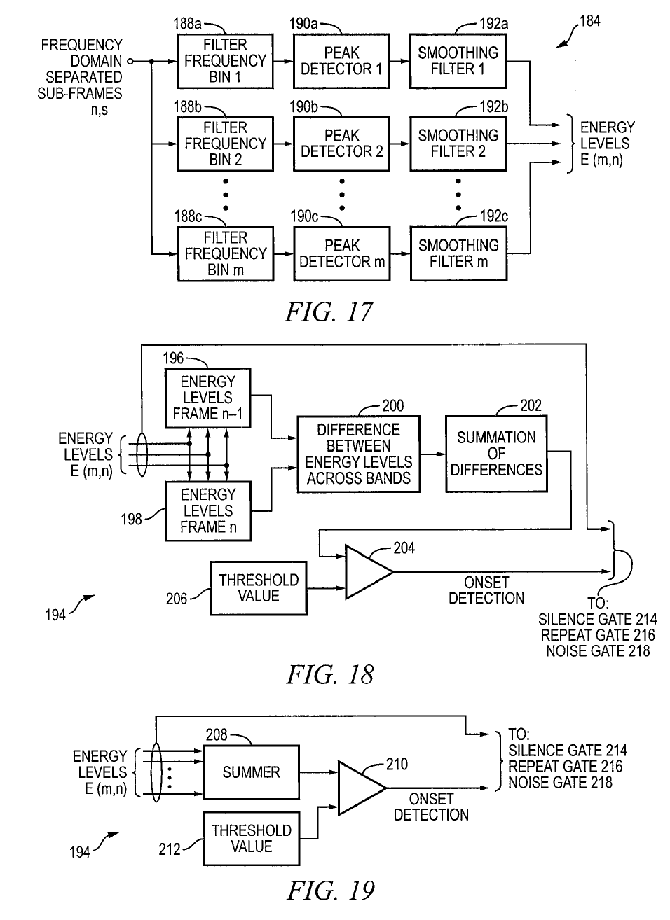

FIG. 16 shows further detail of frequency domain note detector block 182 including energy level isolation block 184 which isolates the energy level of the separated sub-frames 116 into multiple frequency bins. In FIG. 17, energy level isolation block 184 processes each frequency domain separated sub-frame n,s through filter frequency bins 188a-188c to separate and isolate specific frequencies of the audio signal. The filter frequency bins 188a-188c can isolate specific frequency bands in the audio range of 100-10000 Hz. In one embodiment, filter frequency bin 188a is centered at 100 Hz, filter frequency bin 188b is centered at 500 Hz, and filter frequency bin 188c is centered at 1000 Hz. The output of filter frequency bin 188a contains the energy level of the separated sub-frame n,s centered at 100 Hz. The output of filter frequency bin 188b contains the energy level of the separated sub-frame n,s centered at 500 Hz. The output of filter frequency bin 188c contains the energy level of the separated sub-frame n,s centered at 1000 Hz. The output of other filter frequency bins each contain the energy level of the separated sub-frame n,s for a given specific band. Peak detector 190a monitors and stores the peak energy levels of the separated sub-frames n,s centered at 100 Hz. Peak detector 190b monitors and stores the peak energy levels of the separated sub-frames n,s centered at 500 Hz. Peak detector 190c monitors and stores the peak energy levels of the separated sub-frames n,s centered at 1000 Hz. Smoothing filter 192a removes spurious components and otherwise stabilizes the peak energy levels of the separated sub-frames n,s centered at 100 Hz. Smoothing filter 192b removes spurious components and otherwise stabilizes the peak energy levels of the separated sub-frames n,s centered at 500 Hz. Smoothing filter 192c removes spurious components of the peak energy levels and otherwise stabilizes the separated sub-frames n,s centered at 1000 Hz. The output of smoothing filters 192a-192c is the energy level function E(m,n) for each separated sub-frame n,s in each frequency bin 1-m.

The energy levels E(m,n) of one separate sub-frame n−1,s are stored in block 196 of attack detector 194, as shown in FIG. 18. The energy levels of each frequency bin 1-m for the next separated sub-frame n,s, as determined by filter frequency bins 188a-188c, peak detectors 190a-190c, and smoothing filters 192a-192c, are stored in block 198 of attack detector 194. Difference block 200 determines a difference between energy levels of corresponding bins of the present separated sub-frame n,s and the previous separated sub-frame n−1,s. For example, the energy level of frequency bin 1 for separated sub-frame n−1,s is subtracted from the energy level of frequency bin 1 for separated sub-frame n,s. The energy level of frequency bin 2 for separated sub-frame n−1,s is subtracted from the energy level of frequency bin 2 for separated sub-frame n,s. The energy level of frequency bin m for separated sub-frame n−1,s is subtracted from the energy level of frequency bin m for separated sub-frame n,s. The difference in energy levels for each frequency bin 1-m of separated sub-frame n,s and separated sub-frame n−1,s are summed in summer 202.

Summer 202 accumulates the difference in energy levels E(m,n) of each frequency bin 1-m of separated sub-frame n−1,s and separated sub-frame n,s. The onset of a note will occur when the total of the differences in energy levels E(m,n) across the entire monitored frequency bins 1-m for the separated sub-frames n,s exceeds a predetermined threshold value. Comparator 204 compares the output of summer 202 to a threshold value 206. If the output of summer 202 is greater than threshold value 206, then the accumulation of differences in energy levels E(m,n) over the entire frequency spectrum for the separated sub-frames n,s exceeds the threshold value 206 and the onset of a note is detected in the instant separated sub-frame n,s. If the output of summer 202 is less than threshold value 206, then no onset of a note is detected.

At the conclusion of each sub-frame, attack detector 194 will have identified whether the instant separated sub-frame n,s contains the onset of a note, or whether the instant separated sub-frame n,s contains no onset of a note. For example, based on the summation of differences in energy levels E(m,n) of the separated sub-frame n,s over the entire spectrum of frequency bins 1-m exceeding threshold value 206, attack detector 194 may have identified sub-frame 1,s of FIG. 9 as containing the onset of a note, while sub-frame 2,s and sub-frame 3,s of FIG. 9 have no onset of a note. FIG. 5a illustrates the onset of a note at point 150 in sub-frame 1,s (based on the energy levels E(m,n) of the separated sub-frames n,s within frequency bins 1-m) and no onset of a note in sub-frame 2,s or sub-frame 3,s. FIG. 5a has another onset detection of a note at point 152. FIG. 5b shows onset detections of a note at points 154, 156, and 158.

FIG. 19 illustrates another embodiment of attack detector 194 as directly summing the energy levels E(m,n) with summer 208. Summer 208 accumulates the energy levels E(m,n) of each separated sub-frame n,s and each frequency bin 1-m. The onset of a note will occur when the total of the energy levels E(m,n) across the entire monitored frequency bins 1-m for the separated sub-frames n,s exceeds a predetermined threshold value. Comparator 210 compares the output of summer 208 to a threshold value 212. If the output of summer 208 is greater than threshold value 212, then the accumulation of energy levels E(m,n) over the entire frequency spectrum for the separated sub-frames n,s exceeds the threshold value 212 and the onset of a note is detected in the instant the separated sub-frame n,s. If the output of summer 208 is less than threshold value 212, then no onset of a note is detected.

At the conclusion of each separated sub-frame n,s, attack detector 194 will have identified whether the instant separated sub-frame n,s contains the onset of a note, or whether the instant the separated sub-frame n,s contains no onset of a note. For example, based on the summation of energy levels E(m,n) of the separated sub-frames n,s within frequency bins 1-m exceeding threshold value 212, attack detector 194 may have identified sub-frame 1,s of FIG. 9 as containing the onset of a note, while sub-frame 2,s and sub-frame 3,s of FIG. 9 have no onset of a note.

Equation (1) provides another illustration of the onset detection of a note. The function g(m,n) has a value for each frequency bin 1-m and each separated sub-frame n,s. If the ratio of E(m,n)/E(m,n−1), i.e., the energy level of bin m in separated sub-frame n,s to the energy level of bin m in separated sub-frame n−1,s, is less than one, then [E(m,n)/E(m,n−1)]−1 is negative. The energy level of bin m in separated sub-frame n,s is not greater than the energy level of bin m in separated sub-frame n−1,s. The function g(m,n) is zero indicating no initiation of the attack phase and therefore no detection of the onset of a note. If the ratio of E(m,n)/E(m,n−1), i.e., the energy level of bin m in separated sub-frame n,s to the energy level of bin m in separated sub-frame n−1,s, is greater than one (say value of two), then [E(m,n)/E(m,n−1)]−1 is positive, i.e., value of one. The energy level of bin m in separated sub-frame n,s is greater than the energy level of bin m in separated sub-frame n−1,s. The function g(m,n) is the positive value of [E(m,n)/E(m,n−1)]−1 indicating initiation of the attack phase and a possible detection of the onset of a note.

Returning to FIG. 16, attack detector 194 routes the onset detection of a note to silence gate 214, repeat gate 216, and noise gate 218. Not every onset detection of a note is genuine. Silence gate 214 monitors the energy levels E(m,n) of the separated sub-frames n,s after the onset detection of a note. If the energy levels E(m,n) of the separated sub-frames n,s after the onset detection of a note are low due to silence, e.g., −45 dB, then the energy levels E(m,n) of the separated sub-frames n,s that triggered the onset of a note are considered to be spurious and rejected. For example, the artist may have inadvertently touched one or more of strings 52 without intentionally playing a note or chord. The energy levels E(m,n) of the separated sub-frames n,s resulting from the inadvertent contact may have been sufficient to detect the onset of a note, but because playing does not continue, i.e., the energy levels E(m,n) of the separated sub-frames n,s after the onset detection of a note indicate silence, the onset detection is rejected.

Repeat gate 216 monitors the number of onset detections occurring within a time period. If multiple onsets of a note are detected within the repeat detection time period, e.g., 50 ms, then only the first onset detection is recorded. That is, any subsequent onset of a note that, is detected, after the first onset detection, within the repeat detection time period is rejected.

Noise gate 218 monitors the energy levels E(m,n) of the separated sub-frames n,s about the onset detection of a note. If the energy levels E(m,n) of the separated sub-frames n,s about the onset detection of a note are generally in the low noise range, e.g., the energy levels E(m,n) are −90 dB, then the onset detection is considered suspect and rejected as unreliable. A valid onset detection of a note for the instant separated sub-frame n,s is stored in runtime matrix 174.

Returning to FIG. 15, pitch detector block 220 determines fundamental frequency of the frequency domain separated sub-frames n,s. The fundamental frequency is given as a number value, typically in Hz. The pitch detector is a frequency domain parameter or characteristic of each separated sub-frame n,s and is stored as a value in runtime matrix 174 on a frame-by-frame basis.

Note spectral block 222 determines the fundamental frequency and 2nd-nth harmonics of the frequency domain separated sub-frames n,s to analysis the tristimulus of the audio signal. The first tristimulus (tr1) measures the power spectrum of the fundamental frequency. The second tristimulus (tr1) measures an average power spectrum of the 2nd harmonic, 3rd harmonic, and 4th harmonic of the frequency domain separated sub-frames n,s frequency. The third tristimulus (tr3) measures an average power spectrum of the 5th harmonic through the nth harmonic of the frequency domain separated sub-frames n,s frequency. The note spectral is a frequency domain parameter or characteristic of each separated sub-frame n,s and is stored as a value in runtime matrix 174 on a frame-by-frame basis.

Note partial block 224 determines brightness (amplitude) of the frequency domain separated sub-frames n,s. Brightness B can be determined by equation (3). The note partial is a frequency domain parameter or characteristic of each separated sub-frame n,s and is stored as a value in runtime matrix 174 on a frame-by-frame basis.

$$B = 20 log 10 ( \frac{{\sum }_{k = 1}^{N} k * {partial}_{k}}{{\sum }_{k = 1}^{N} {partial}_{k}} * \frac{{f}_{0}}{1000} ) \qquad ( 3 )$$

where:
f₀ is the fundamental frequency of the audio signal
partialₖ is the kth harmonic partial magnitude of the audio signal
N is the number of harmonic partial above the noise gate (e.g. −45 dB)

Note inharmonicity block 226 determines the fundamental frequency and 2nd-nth harmonics of the frequency domain separated sub-frames n,s. Ideally, the 2nd-nth harmonics are integer multiples of the fundamental frequency. Some musical instruments can be distinguished and identified by determining whether the integer multiple relationship holds between the fundamental frequency and 2nd-nth harmonics. If the 2nd-nth harmonics is not an integer multiple of the fundamental frequency, then the degree of separation from the integer multiple relationship is indicative of the type of instrument. For example, the 2nd harmonic of piano 64 is typically not an integer multiple of the fundamental frequency. The note inharmonicity is a frequency domain parameter or characteristic of each separated sub-frame n,s and is stored as a value in runtime matrix 174 on a frame-by-frame basis.

Attack frequency block 228 determines the frequency content of the attack phase the separated sub-frames n,s. In particular, the brightness (amplitude) of the higher components are measured and recorded. The attack frequency is a frequency domain parameter or characteristic of each separated sub-frame n,s and is stored as a value in runtime matrix 174 on a frame-by-frame basis.

Harmonic derivative block 230 determines the harmonic derives of the 2nd-nth harmonics of the frequency domain separated sub-frame n,s in order to measure rate of change of the frequency components. The harmonic derivative is a frequency domain parameter or characteristic of each separated sub-frame n,s and is stored as a value in runtime matrix 174 on a frame-by-frame basis.

Runtime matrix 174 contains the frequency domain parameters determined in frequency domain analysis block 106 and the time domain parameters determined in time domain analysis block 108. Each time domain parameter and frequency domain parameter 1-j has a numeric parameter value PVn,j stored in runtime matrix 174 on a frame-by-frame basis, where n is the frame along the time sequence 112 and j is the parameter. For example, the beat detector parameter 1 has value PV1,1 in sub-frame 1,s, value PV2,1 in sub-frame 2,s, and value PVn,1 in sub-frame n,s; pitch detector parameter 2 has value PV1,2 in sub-frame 1,s, value PV2,2 in sub-frame 2,s, and value PVn,2 in sub-frame n,s; loudness factor parameter 3 has value PV1,3 in sub-frame 1,s, value PV2,3 in sub-frame 2,s, and value PVn,3 in sub-frame n,s; and so on. Table 1 shows runtime matrix 174 with the time domain and frequency domain parameter values PVn,j generated during the runtime analysis. The time domain and frequency domain parameter values PVn,j are characteristic of specific sub-frames and therefore useful in distinguishing between the sub-frames.

TABLE 1
Runtime matrix 174 with time domain parameters and
frequency domain parameters from runtime analysis

| | Sub-frame | Sub-frame | | Sub-frame |
|---|---|---|---|---|
| Parameter | 1, s | 2, s | . . . | n, s |
| Beat detector | PV1, 1 | PV2, 1 | | PVn, 1 |
| Pitch detector | PV1, 2 | PV2, 2 | | PVn, 2 |
| Loudness factor | PV1, 3 | PV2, 3 | | PVn, 3 |
| Note temporal factor | PV1, 4 | PV2, 4 | | PVn, 4 |
| Note spectral factor | PV1, 5 | PV2, 5 | | PVn, 5 |
| Note partial factor | PV1, 6 | PV2, 6 | | PVn, 6 |
| Note inharmonicity factor | PV1, 7 | PV2, 7 | | PVn, 7 |
| Attack frequency factor | PV1, 8 | PV2, 8 | | PVn, 8 |
| Harmonic derivative factor | PV1, 9 | PV2, 9 | | PVn, 9 |

Table 2 shows one separated sub-frame n,s of runtime matrix 174 with the time domain and frequency domain parameters generated by frequency domain analysis block 106 and time domain analysis block 108 assigned sample numeric values for an audio signal originating from a classical style. Runtime matrix 174 contains time domain and frequency domain parameter values PVn,j for other sub-frames of the audio signal originating from the classical style, as per Table 1.

TABLE 2
Time domain and frequency domain parameters from runtime
analysis of one sub-frame of classical style

| Parameter | Sub-frame value |
|---|---|
| Beat detector | 68 |
| Pitch detector | 428 |
| Loudness factor | 0.42 |
| Note temporal factor | 0.62, 0.25, 0.81, 0.33 |
| Note spectral factor | 1.00, 0.83, 0.39 |
| Note partial factor | 0.94 |
| Note inharmonicity factor | 0.57 |
| Attack frequency factor | 0.16 |
| Harmonic derivative factor | 0.28 |

Table 3 shows one separated sub-frame n,s of runtime matrix 174 with the time domain and frequency domain parameters generated by frequency domain analysis block 106 and time domain analysis block 108 assigned sample numeric values for an audio signal originating from a rock style. Runtime matrix 174 contains time domain and frequency domain parameter values PVn,j for other sub-frames of the audio signal originating from the rock style, as per Table 1.

TABLE 3
Time domain parameters and frequency domain parameters
from runtime analysis of one sub-frame of rock style

| Parameter | Sub-frame value |
|---|---|
| Beat detector | 113 |
| Pitch detector | 267 |
| Loudness factor | 0.59 |
| Note temporal factor | 0.25, 0.23, 0.32, 0.73 |
| Note spectral factor | 1.00, 0.33, 0.11 |
| Note partial factor | 0.27 |
| Note inharmonicity factor | 0.17 |
| Attack frequency factor | 0.28 |
| Harmonic derivative factor | 0.20 |

Returning to FIG. 6, frame signature database 92 is maintained in a memory component of audio amplifier 70 and contains a plurality of frame signature records 1, 2, 3, . . . i with each frame signature record having time domain parameters and frequency domain parameters corresponding to runtime matrix 174. In addition, the frame signature records 1-i contain weighting factors 1, 2, 3, . . . j for each time domain and frequency domain parameter, and a plurality of control parameters 1, 2, 3, . . . k.

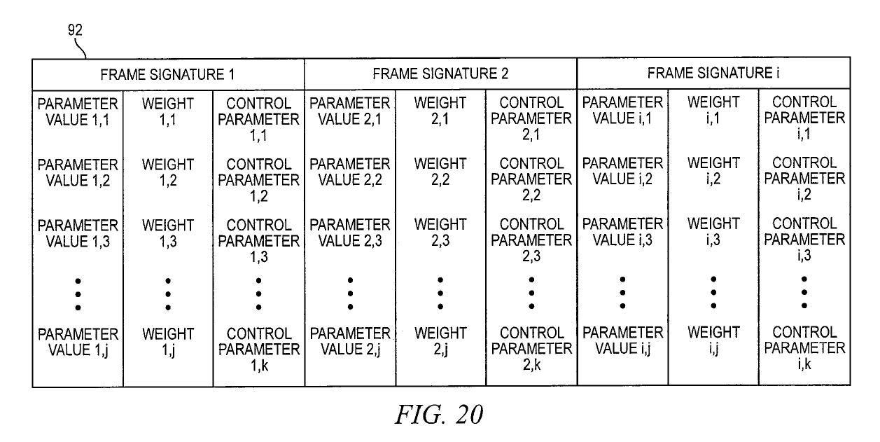

FIG. 20 shows database 92 with time domain and frequency domain parameters 1-j for each frame signature 1-i, weighting factors 1-j for each frame signature 1-i, and control parameters 1-k for each frame signature 1-i. Each frame signature record i is defined by the parameters 1-j, and associated weights 1-j, that are characteristic of the frame signature and will be used to identify an incoming sub-frame n,s from runtime matrix 174 as being best matched or most closely correlated to frame signature i. Once the incoming sub-frame n,s from runtime matrix 174 is matched to a particular frame signature i, adaptive intelligence control 94 uses control parameters 1-k for the matching frame signature to set the operating state of the signal processing blocks 72-84 of audio amplifier 70. For example, in a matching frame signature record i, control parameter i,1 sets the operating state of pre-filter block 72; control parameter i,2 sets the operating state of pre-effects block 74; control parameter i,3 sets the operating state of non-linear effects block 76; control parameter i,4 sets the operating state of user-defined modules 78; control parameter i,5 sets the operating state of post-effects block 80; control parameter i,6 sets the operating state of post-filter block 82; and control parameter i,7 sets the operating state of power amplification block 84.

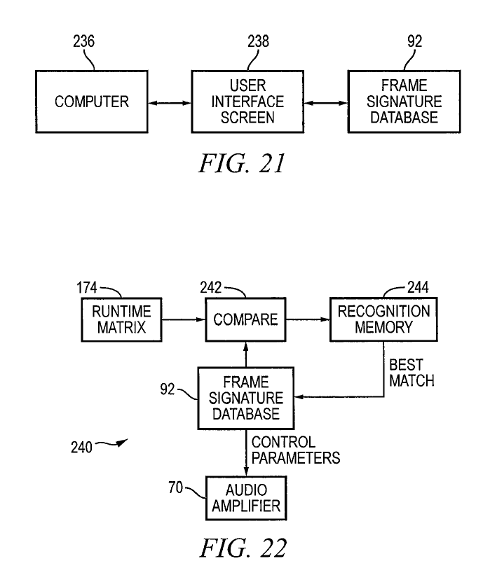

The time domain parameters and frequency domain parameters in frame signature database 92 contain values preset by the manufacturer, or entered by the user, or learned over time from one or more instruments and one or more vocals. The factory or manufacturer of audio amplifier 70 can initially preset the values of time domain and frequency domain parameters 1-j, as well as weighting factors 1-j and control parameters 1-k. The user can change time domain and frequency domain parameters 1-j, weighting factors 1-j, and control parameters 1-k for each frame signature 1-i in database 92 directly using computer 236 with user interface screen or display 238, see FIG. 21. The values for time domain and frequency domain parameters 1-j, weighting factors 1-j, and control parameters 1-k are presented with interface screen 236 to allow the user to enter updated values for each frame signature 1-i in database 92.

In another embodiment, time domain and frequency domain parameters 1-j, weighting factors 1-j, and control parameters 1-k can be learned by the artist playing guitar 60, drums 62, or piano 64, or singing into microphone 66. The artist sets audio amplifier 70 to a learn mode. The artists repetitively play the instruments or sing into the microphone. The frequency domain analysis 106 and time domain analysis 108 of FIG. 7 create a runtime matrix 174 with associated frequency domain parameters and time domain parameters 1-j for each separated sub-frame n,s, as defined in FIG. 9. The frequency domain parameters and time domain parameters for each separated sub-frame n,s are accumulated and stored in database 92.

The artist can make manual adjustments to audio amplifier 70 via front control panel 30. Audio amplifier 70 learns control parameters 1-k associated with the separated sub-frame n,s by the settings of the signal processing blocks 72-84 as manually set by the artist. When learn mode is complete, the frame signature records in database 92 are defined with the frame signature parameters being an average of the frequency domain parameters and time domain parameters 1-j accumulated in database 92, and an average of the control parameters 1-k taken from the manual adjustments of the signal processing blocks 72-84 of audio amplifier 70 in database 92. In one embodiment, the average is a root mean square of the series of accumulated frequency domain and time domain parameters 1-j and accumulated control parameters 1-k in database 92.

Weighting factors 1-j can be learned by monitoring the learned time domain and frequency domain parameters 1-j and increasing or decreasing the weighting factors based on the closeness or statistical correlation of the comparison. If a particular parameter exhibits a consistent statistical correlation, then the weight factor for that parameter can be increased. If a particular parameter exhibits a diverse statistical diverse correlation, then the weighting factor for that parameter can be decreased.

Once the time domain and frequency domain parameters 1-j, weighting factors 1-j, and control parameters 1-k of frame signatures 1-i are established for database 92, the parameters 1-j in runtime matrix 174 can be compared on a frame-by-frame basis to each frame signature 1-i to find a best match or closest correlation. In normal play mode, the artists sing lyrics and play instruments to generate an audio signal having a time sequence of frames. For each frame, runtime matrix 174 is populated with time domain parameters and frequency domain parameters determined from a time domain analysis and frequency domain analysis of the audio signal, as described in FIGS. 6-19.

The time domain and frequency domain parameters 1-j for each separated sub-frame n,s in runtime matrix 174 and the parameters 1-j in each frame signature 1-i are compared on a one-by-one basis and the differences are recorded. FIG. 22 shows a recognition detector 240 with compare block 242 for determining the difference between time domain and frequency domain parameters 1-j for one sub-frame in runtime matrix 174 and the parameters 1-j in each frame signature 1-i. For example, for each parameter of separated sub-frame 1,1, compare block 242 determines the difference between the parameter value in runtime matrix 174 and the parameter value in frame signature 1 and stores the difference in recognition memory 244. The differences between the parameters 1-j of each separated sub-frame 1,1 in runtime matrix 174 and the parameters 1-j of frame signature 1 are summed to determine a total difference value between the parameters 1-j of separated sub-frame 1,1 and the parameters 1-j of frame signature 1.

Next, for each parameter of separated sub-frame 1,1, compare block 242 determines the difference between the parameter value in runtime matrix 174 and the parameter value in frame signature 2 and stores the difference in recognition memory 244. The differences between the parameters 1-j of separated sub-frame 1,1 in runtime matrix 174 and the parameters 1-j of frame signature 2 are summed to determine a total difference value between the parameters 1-j of separated sub-frame 1,1 and the parameters 1-j of frame signature 2.

The time domain parameters and frequency domain parameters 1-j in runtime matrix 174 for separated sub-frame 1,1 are compared to the time domain and frequency domain parameters 1-j in the remaining frame signatures 3-i in database 92, as described for frame signatures 1 and 2. The minimum total difference between the parameters 1-j of separated sub-frame 1,1 of runtime matrix 174 and the parameters 1-j of frame signatures 1-i is the best match or closest correlation and the frame associated with separated sub-frame 1,1 of runtime matrix 174 is identified with the frame signature having the minimum total difference between corresponding parameters. In this case, the time domain and frequency domain parameters 1-j of separated sub-frame 1,1 in runtime matrix 174 are more closely aligned to the time domain and frequency domain parameters 1-j in frame signature 1.

With time domain parameters and frequency domain parameters 1-j of separated sub-frame 1,1 in runtime matrix 174 matched to frame signature 1, adaptive intelligence control block 94 of FIG. 7 uses the control parameters 1-k associated with the matching frame signature 1 in database 92 to control operation of the signal processing blocks 72-84 of audio amplifier 70. The audio signal is processed through pre-filter block 72, pre-effects block 74, non-linear effects block 76, user-defined modules 78, post-effects block 80, post-filter block 82, and power amplification block 84, each operating as set by control parameter 1,1, control parameter 1,2, through control parameter 1,k of frame signature 1, respectively. The enhanced audio signal is routed to speakers 46 in automobile 24. The listener hears the reproduced audio signal enhanced in realtime with characteristics determined by the dynamic content of the audio signal.

The process is repeated for separated sub-frames 1,2 through 1,s. In one embodiment, the control parameters 1,k of sub-frames 1,1 through 1,s each control different functions within signal processing blocks 72-84 of audio amplifier 70. Alternatively, since the separated sub-frames 1,1 through 1,s occur within the same time period, the control parameters 1,k can be an average or other combination of the control parameters determined for each separated sub-frames 1,1 through 1,s.

The time domain and frequency domain parameters 1-j for each separated sub-frame 2,1 through 2,s in runtime matrix 174 and the parameters 1-j in each frame signature 1-i are compared on a one-by-one basis and the differences are recorded. For each parameter 1-j of separated sub-frame 2,1, compare block 242 determines the difference between the parameter value in runtime matrix 174 and the parameter value in frame signature i and stores the difference in recognition memory 244. The differences between the parameters 1-j of separated sub-frame 2,1 in runtime matrix 174 and the parameters 1-j of frame signature i are summed to determine a total difference value between the parameters 1-j of separated sub-frame 2,1 and the parameters 1-j of frame signature i. The minimum total difference between the parameters 1-j of separated sub-frame 2,1 of runtime matrix 174 and the parameters 1-j of frame signatures 1-i is the best match or closest correlation and the frame associated with separated sub-frame 2,1 of runtime matrix 174 is identified with the frame signature having the minimum total difference between corresponding parameters. In this case, the time domain and frequency domain parameters 1-j of separated sub-frame 2,1 in runtime matrix 174 are more closely aligned to the time domain and frequency domain parameters 1-j in frame signature 2. Adaptive intelligence control block 94 uses the control parameters 1-k associated with the matching frame signature 2 in database 92 to control operation of the signal processing blocks 72-84 of audio amplifier 70.

The process is repeated for separated sub-frames 2,2 through 2,s. In one embodiment, the control parameters 1,k of sub-frames 2,1 through 2,s each control different functions within signal processing blocks 72-84 of audio amplifier 70. Alternatively, since the separated sub-frames 2,1 through 2,s occur within the same time period, the control parameters 1,k can be an average or other combination of the control parameters determined for each separated sub-frames 2,1 through 2,s. The process continues for each separated sub-frame n,s of runtime matrix 174.

In another embodiment, the time domain and frequency domain parameters 1-j for each separated sub-frame n,s in runtime matrix 174 and the parameters 1-j in each frame signature 1-i are compared on a one-by-one basis and the weighted differences are recorded. For each parameter of separated sub-frame 1,1, compare block 242 determines the weighted difference between the parameter value in runtime matrix 174 and the parameter value in frame signature 1 as determined by weight 1,j and stores the weighted difference in recognition memory 244. The weighted differences between the parameters 1-j of separated sub-frame 1,1 in runtime matrix 174 and the parameters 1-j of frame signature 1 are summed to determine a total weighted difference value between the parameters 1-j of separated sub-frame 1,1 and the parameters 1-j of frame signature 1.

Next, for each parameter of separated sub-frame 1,1, compare block 242 determines the weighted difference between the parameter value in runtime matrix 174 and the parameter value in frame signature 2 by weight 2,j and stores the weighted difference in recognition memory 244. The weighted differences between the parameters 1-j of separated sub-frame 1,1 and the parameters 1-j of frame signature 2 are summed to determine a total weighted difference value between the parameters 1-j of separated sub-frame 1,1 and the parameters 1-j of frame signature 2.

The time domain parameters and frequency domain parameters 1-j in runtime matrix 174 for separated sub-frame 1,1 are compared to the time domain and frequency domain parameters 1-j in the remaining frame signatures 3-i in database 92, as described for frame signatures 1 and 2. The minimum total weighted difference between the parameters 1-j of separated sub-frame 1,1 in runtime matrix 174 and the parameters 1-j of frame signatures 1-i is the best match or closest correlation and the frame associated with separated sub-frame 1,1 of runtime matrix 174 is identified with the frame signature having the minimum total weighted difference between corresponding parameters. Adaptive intelligence control block 94 uses the control parameters 1-k in database 92 associated with the matching frame signature to control operation of the signal processing blocks 72-84 of audio amplifier 70.

The process is repeated for separated sub-frames 1,2 through 1,s. In one embodiment, the control parameters 1,k of sub-frames 1,1 through 1,s each control different functions within signal processing blocks 72-84 of audio amplifier 70. Alternatively, since the separated sub-frames 1,1 through 1,s occur within the same time period, the control parameters 1,k can be an average or other combination of the control parameters determined for each separated sub-frames 1,1 through 1,s.

The time domain and frequency domain parameters 1-j for separated sub-frame 2,1 in runtime matrix 174 and the parameters 1-j in each frame signature 1-i are compared on a one-by-one basis and the weighted differences are recorded. For each parameter 1-j of separated sub-frame 2,1, compare block 242 determines the weighted difference between the parameter value in runtime matrix 174 and the parameter value in frame signature by weight i,j and stores the weighted difference in recognition memory 244. The weighted differences between the parameters 1-j of separated sub-frame 2,1 in runtime matrix 174 and the parameters 1-j of frame signature i are summed to determine a total weighted difference value between the parameters 1-j of separated sub-frame 2,1 and the parameters 1-j of frame signature i. The minimum total weighted difference between the parameters 1-j of separated sub-frame 2,1 of runtime matrix 174 and the parameters 1-j of frame signatures 1-i is the best match or closest correlation and the frame associated with separated sub-frame 2,1 of runtime matrix 174 is identified with the frame signature having the minimum total weighted difference between corresponding parameters. Adaptive intelligence control block 94 uses the control parameters 1-k in database 92 associated with the matching frame signature to control operation of the signal processing blocks 72-84 of audio amplifier 70.

The process is repeated for separated sub-frames 2,2 through 2,s. In one embodiment, the control parameters 1,k of sub-frames 2,1 through 2,s each control different functions within signal processing blocks 72-84 of audio amplifier 70. Alternatively, since the separated sub-frames 2,1 through 2,s occur within the same time period, the control parameters 1,k can be an average or other combination of the control parameters determined for each separated sub-frames 2,1 through 2,s. The process continues for each separated sub-frame n,s of runtime matrix 174.

In an illustrative numeric example of the parameter comparison process to determine a best match or closest correlation between the time domain and frequency domain parameters 1-j for each frame in runtime matrix 174 and parameters 1-j for each frame signature 1-i, Table 4 shows time domain and frequency domain parameters 1-j with sample parameter values for frame signature 1 (classical style) of database 92. Table 5 shows time domain and frequency domain parameters 1-j with sample parameter values for frame signature 2 (rock style) of database 92.

TABLE 4
Time domain parameters and frequency domain parameters
for frame signature 1 (classical style)

| Parameter | Value | Weighting |
|---|---|---|
| Beat detector | 60 | 0.83 |
| Pitch detector | 440 | 0.67 |
| Loudness factor | 0.46 | 0.72 |
| Note temporal factor | 0.60, 0.25, 0.78, 0.30 | 0.45 |
| Note spectral factor | 1.00, 0.85, 0.35 | 1.00 |
| Note partial factor | 0.90 | 0.37 |
| Note inharmonicity factor | 0.50 | 0.88 |
| Attack frequency factor | 0.12 | 0.61 |
| Harmonic derivative factor | 0.25 | 0.70 |

TABLE 5
Time domain parameters and frequency domain
parameters in frame signature 2 (rock style)

| Parameter | Value | Weighting |
|---|---|---|
| Beat detector | 120 | 0.80 |
| Pitch detector | 250 | 0.71 |
| Loudness factor | 0.55 | 0.65 |
| Note temporal factor | 0.25, 0.20, 0.30, 0.68 | 0.35 |
| Note spectral factor | 1.00, 0.25, 0.15 | 1.00 |
| Note partial factor | 0.25 | 0.27 |
| Note inharmonicity factor | 0.10 | 0.92 |
| Attack frequency factor | 0.26 | 0.69 |
| Harmonic derivative factor | 0.20 | 0.74 |

The time domain and frequency domain parameters 1-j for separated sub-frames n,s in runtime matrix 174 and the parameters 1-j in each frame signatures 1-i are compared on a one-by-one basis and the differences are recorded. For example, the beat detector parameter of separated sub-frame 1,1 in runtime matrix 174 has a value of 68 (see Table 2) and the beat detector parameter in frame signature 1 has a value of 60 (see Table 4). FIG. 22 shows a recognition detector 240 with compare block 242 for determining the difference between time domain and frequency domain parameters 1-j for one separated sub-frame n,s in runtime matrix 174 and the parameters 1-j in frame signature i. The difference 68−60 between separated sub-frame 1,1 and frame signature 1 is stored in recognition memory 244. The pitch detector parameter of separated sub-frame 1,1 in runtime matrix 174 has a value of 428 (see Table 2) and the pitch detector parameter in frame signature 1 has a value of 440 (see Table 4). Compare block 242 determines the difference 428−440 and stores the difference in recognition memory 244. For each parameter of separated sub-frame 1,1, compare block 242 determines the difference between the parameter value in runtime matrix 174 and the parameter value in frame signature 1 and stores the difference in recognition memory 244. The differences between the parameters 1-j of separated sub-frame 1,1 and the parameters 1-j of frame signature 1 are summed to determine a total difference value between the parameters 1-j of separated sub-frame 1,1 and the parameters 1-j of frame signature 1.

Next, the beat detector parameter of separated sub-frame 1,1 in runtime matrix 174 has a value of 68 (see Table 2) and the beat detector parameter in frame signature 2 has a value of 120 (see Table 5). Compare block 242 determines the difference 68−120 and stores the difference between separated sub-frame 1,1 and frame signature 2 in recognition memory 244. The pitch detector parameter of separated sub-frame 1,1 in runtime matrix 174 has a value of 428 (see Table 2) and the pitch detector parameter in frame signature 2 has a value of 250 (see Table 5). Compare block 242 determines the difference 428−250 and stores the difference in recognition memory 244. For each parameter of separated sub-frame 1,1, compare block 212 determines the difference between the parameter value in runtime matrix 174 and the parameter value in frame signature 2 and stores the difference in recognition memory 244. The differences between the parameters 1-j in runtime matrix 174 for separated sub-frame 1,1 and the parameters 1-j of frame signature 2 are summed to determine a total difference value between the parameters 1-j in runtime matrix 174 for separated sub-frame 1,1 and the parameters 1-j of frame signature 2.

The time domain and frequency domain parameters 1-j in runtime matrix 174 for separated sub-frame 1,1 are compared to the time domain and frequency domain parameters 1-j in the remaining frame signatures 3-i in database 92, as described for frame signatures 1 and 2. The minimum total difference between the parameters 1-j in runtime matrix 174 for separated sub-frame 1,1 and the parameters 1-j of frame signatures 1-i is the best match or closest correlation. In this case, the time domain and frequency domain parameters 1-j in runtime matrix 174 for separated sub-frame 1,1 are more closely aligned to the time domain and frequency domain parameters 1-j in frame signature 1. Separated sub-frame 1,1 of runtime matrix 174 is identified as a frame of a classical style composition.

With time domain parameters and frequency domain parameters 1-j of separated sub-frame 1,1 in runtime matrix 174 generated from the audio signal matched to frame signature 1, adaptive intelligence control block 94 of FIG. 6 uses the control parameters 1-k in database 92 associated with the matching frame signature 1 to control operation of the signal processing blocks 72-84 of audio amplifier 70. The control parameter 1,1, control parameter 1,2, through control parameter 1,k under frame signature 1 each have a numeric value, e.g., 1-10. For example, control parameter 1,1 has a value 5 and sets the operating state of pre-filter block 72 to have a low-pass filter function at 200 Hz; control parameter 1,2 has a value 7 and sets the operating state of pre-effects block 74 to engage a reverb sound effect; control parameter 1,3 has a value 9 and sets the operating state of non-linear effects block 76 to introduce distortion; control parameter 1,4 has a value 1 and sets the operating state of user-defined modules 78 to add a drum accompaniment; control parameter 1,5 has a value 3 and sets the operating state of post-effects block 80 to engage a hum canceller sound effect; control parameter 1,6 has a value 4 and sets the operating state of post-filter block 82 to enable bell equalization; and control parameter 1,7 has a value 8 and sets the operating state of power amplification block 84 to increase amplification by 3 dB. The audio signal is processed through pre-filter block 72, pre-effects block 74, non-linear effects block 76, user-defined modules 78, post-effects block 80, post-filter block 82, and power amplification block 84, each operating as set by control parameter 1,1, control parameter 1,2, through control parameter 1,k of frame signature 1. The enhanced audio signal is routed to speaker 46 in automobile 24. The listener hears the reproduced audio signal enhanced in realtime with characteristics determined by the dynamic content of the audio signal.

The control parameters 1,k of sub-frames 1,1 through 1,s each control different functions within signal processing blocks 72-84 of audio amplifier 70. Alternatively, since the separated sub-frames 1,1 through 1,s occur within the same time period, the control parameters 1,k can be an average or other combination of the control parameters determined for each separated sub-frames 1,1 through 1,s.

Next, the time domain and frequency domain parameters 1-j for separated sub-frame 2,1 in runtime matrix 174 and the parameters 1-j in each frame signatures 1-i are compared on a one-by-one basis and the differences are recorded. For each parameter 1-j of separated sub-frame 2,1, compare block 242 determines the difference between the parameter value in runtime matrix 174 and the parameter value in frame signature i and stores the difference in recognition memory 244. The differences between the parameters 1-j of separated sub-frame 2,1 and the parameters 1-j of frame signature i are summed to determine a total difference value between the parameters 1-j of separated sub-frame 2,1 and the parameters 1-j of frame signature i. The minimum total difference between the parameters 1-j of separated sub-frame 2,1 of runtime matrix 174 and the parameters 1-j of frame signatures 1-i is the best match or closest correlation. Separated sub-frame 2,1 of runtime matrix 174 is identified with the frame signature having the minimum total difference between corresponding parameters. In this case, the time domain and frequency domain parameters 1-j of separated sub-frame 2,1 in runtime matrix 174 are more closely aligned to the time domain and frequency domain parameters 1-j in frame signature 1. Separated sub-frame 2,1 of runtime matrix 174 is identified as another frame for a classical style composition. Adaptive intelligence control block 94 uses the control parameters 1-k in database 92 associated with the matching frame signature 1 to control operation of the signal processing blocks 72-84 of audio amplifier 70.

The control parameters 1,k of sub-frames 2,1 through 2,s each control different functions within signal processing blocks 72-84 of audio amplifier 70. Alternatively, since the separated sub-frames 2,1 through 2,s occur within the same time period, the control parameters 1,k can be an average or other combination of the control parameters determined for each separated sub-frames 2,1 through 2,s. The process continues for each separated sub-frame n,s of runtime matrix 174.

In another numeric example, the beat detector parameter of separated sub-frame 1,1 in runtime matrix 174 has a value of 113 (see Table 3) and the beat detector parameter in frame signature 1 has a value of 60 (see Table 4). The difference 113−60 between separated sub-frame 1,1 and frame signature 1 is stored in recognition memory 244. The pitch detector parameter of separated sub-frame 1,1 in runtime matrix 174 has a value of 267 (see Table 3) and the pitch detector parameter in frame signature 1 has a value of 440 (see Table 4). Compare block 242 determines the difference 267−440 and stores the difference in recognition memory 244. For each parameter of separated sub-frame 1,1, compare block 242 determines the difference between the parameter value in runtime matrix 174 and the parameter value in frame signature 1 and stores the difference in recognition memory 244. The differences between the parameters 1-j of separated sub-frame 1,1 in runtime matrix 174 and the parameters 1-j of frame signature 1 are summed to determine a total difference value between the parameters 1-j of separated sub-frame 1,1 and the parameters 1-j of frame signature 1.

Next, the beat detector parameter of separated sub-frame 1,1 in runtime matrix 174 has a value of 113 (see Table 3) and the beat detector parameter in frame signature 2 has a value of 120 (see Table 5). Compare block 242 determines the difference 113−120 and stores the difference in recognition memory 244. The pitch detector parameter of separated sub-frame 1,1 in runtime matrix 174 has a value of 267 (see Table 3) and the pitch detector parameter in frame signature 2 has a value of 250 (see Table 5). Compare block 242 determines the difference 267−250 and stores the difference in recognition memory 244. For each parameter of separated sub-frame 1,1, compare block 242 determines the difference between the parameter value in runtime matrix 174 and the parameter value in frame signature 2 and stores the difference in recognition memory 244. The differences between the parameters 1-j of separated sub-frame 1,1 and the parameters 1-j of frame signature 2 are summed to determine a total difference value between the parameters 1-j of separated sub-frame 1,1 and the parameters 1-j of frame signature 2.

The time domain and frequency domain parameters 1-j in runtime matrix 174 for separated sub-frame 1,1 are compared to the time domain and frequency domain parameters 1-j in the remaining frame signatures 3-i in database 92, as described for frame signatures 1 and 2. The minimum total difference between the parameters 1-j of separated sub-frame 1,1 of runtime matrix 174 and the parameters 1-j of frame signatures 1-i is the best match or closest correlation. Separated sub-frame 1,1 of runtime matrix 174 is identified with the frame signature having the minimum total difference between corresponding parameters. In this case, the time domain and frequency domain parameters 1-j of separated sub-frame 1,1 in runtime matrix 174 are more closely aligned to the time domain and frequency domain parameters 1-j in frame signature 2. Separated sub-frame 1,1 of runtime matrix 174 is identified as a frame of a rock style composition.

With time domain parameters and frequency domain parameters 1-j of separated sub-frame 1,1 in runtime matrix 174 generated from the analog signal matched to frame signature 2, adaptive intelligence control block 94 of FIG. 6 uses the control parameters 1-k in database 92 associated with the matching frame signature 2 to control operation of the signal processing blocks 72-84 of audio amplifier 70. The audio signal is processed through pre-filter block 72, pre-effects block 74, non-linear effects block 76, user-defined modules 78, post-effects block 80, post-filter block 82, and power amplification block 84, each operating as set by control parameter 2,1, control parameter 2,2, through control parameter 2,k of frame signature 2, respectively. The enhanced audio signal is routed to speaker 46 in automobile 24. The listener hears the reproduced audio signal enhanced in realtime with characteristics determined by the dynamic content of the audio signal.

The control parameters 2,k of sub-frames 1,1 through 1,s each control different functions within signal processing blocks 72-84 of audio amplifier 70. Alternatively, since the separated sub-frames 1,1 through 1,s occur within the same time period, the control parameters 2,k can be an average or other combination of the control parameters determined for each separated sub-frames 1,1 through 1,s.

The time domain and frequency domain parameters 1-j for separated sub-frame 2,1 in runtime matrix 174 and the parameters 1-j in each frame signatures 1-i are compared on a one-by-one basis and the differences are recorded. For each parameter 1-j of separated sub-frame 2,1, compare block 212 determines the difference between the parameter value in runtime matrix 174 and the parameter value in frame signature i and stores the difference in recognition memory 244. The differences between the parameters 1-j of separated sub-frame 2,1 and the parameters 1-j of frame signature i are summed to determine a total difference value between the parameters 1-j of frame 2 and the parameters 1-j of frame signature i. The minimum total difference, between the parameters 1-j of separated sub-frame 2,1 of runtime matrix 174 and the parameters 1-j of frame signatures 1-i is the best match or closest correlation. The separate sub-frame 2,1 of runtime matrix 174 is identified with the frame signature having the minimum total difference between corresponding parameters. In this case, the time domain and frequency domain parameters 1-j of separated sub-frame 2,1 in runtime matrix 174 are more closely aligned to the time domain and frequency domain parameters 1-j in frame signature 2. The separated sub-frame 2,1 of runtime matrix 174 is identified as another frame of a rock style composition. Adaptive intelligence control block 94 uses the control parameters 1-k in database 92 associated with the matching frame signature 2 to control operation of the signal processing blocks 72-84 of audio amplifier 70.

The control parameters 2,k of sub-frames 2,1 through 2,s each control different functions within signal processing blocks 72-84 of audio amplifier 70. Alternatively, since the separated sub-frames 2,1 through 2,s occur within the same time period, the control parameters 2,k can be an average or other combination of the control parameters determined for each separated sub-frames 2,1 through 2,s. The process continues for each separated sub-frame n,s of runtime matrix 174.

In another embodiment, the time domain and frequency domain parameters 1-j for each separated sub-frame n,s in runtime matrix 174 and the parameters 1-j in each frame signatures 1-i are compared on a one-by-one basis and the weighted differences are recorded. For example, the beat detector parameter of separated sub-frame 1,1 in runtime matrix 174 has a value of 68 (see Table 2) and the beat detector parameter in frame signature 1 has a value of 60 (see Table 4). Compare block 242 determines the weighted difference (68−60)*weight 1,1 and stores the weighted difference in recognition memory 244. The pitch detector parameter of separated sub-frame 1,1 in runtime matrix 174 has a value of 428 (see Table 2) and the pitch detector parameter in frame signature 1 has a value of 440 (see Table 4). Compare block 242 determines the weighted difference (428−440)*weight 1,2 and stores the weighted difference in recognition memory 244. For each parameter of separated sub-frame 1,1, compare block 242 determines the weighted difference between the parameter value in runtime matrix 174 and the parameter value in frame signature 1 as determined by weight 1,j and stores the weighted difference in recognition memory 244. The weighted differences between the parameters 1-j of separated sub-frame 1,1 and the parameters 1-j of frame signature 1 are summed to determine a total weighted difference value between the parameters 1-j of separated sub-frame 1,1 and the parameters 1-j of frame signature 1.

Next, the beat detector parameter of separated sub-frame 1,1 in runtime matrix 174 has a value of 68 (see Table 2) and the beat detector parameter in frame signature 2 has a value of 120 (see Table 5). Compare block 242 determines the weighted difference (68−120)*weight 2,1 and stores the weighted difference in recognition memory 244. The pitch detector parameter of separated sub-frame 1,1 in runtime matrix 174 has a value of 428 (see Table 2) and the pitch detector parameter in frame signature 2 has a value of 250 (see Table 5). Compare block 242 determines the weighted difference (428−250)*weight 2,2 and stores the weighted difference in recognition memory 244. For each parameter of separated sub-frame 1,1, compare block 212 determines the weighted difference between the parameter value in runtime matrix 174 and the parameter value in frame signature 2 by weight 2,j and stores the weighted difference in recognition memory 244. The weighted differences between the parameters 1-j of frame 1 in runtime matrix 174 and the parameters 1-j of frame signature 2 are summed to determine a total weighted difference value between the parameters 1-j of frame 1 and the parameters 1-j of frame signature 2.

The time domain and frequency domain parameters 1-j in runtime matrix 174 for separated sub-frame 1,1 are compared to the time domain and frequency domain parameters 1-j in the remaining frame signatures 3-i in database 92, as described for frame signatures 1 and 2. The minimum total weighted difference between the parameters 1-j of separated sub-frame 1,1 of runtime matrix 174 and the parameters 1-j of frame signatures 1-i is the best match or closest correlation. The separated sub-frame 1,1 of runtime matrix 174 is identified with the frame signature having the minimum total weighted difference between corresponding parameters. Adaptive intelligence control block 94 uses the control parameters 1-k in database 92 associated with the matching frame signature to control operation of the signal processing blocks 72-84 of audio amplifier 70.

The control parameters 1,k of sub-frames 1,1 through 1,s each control different functions within signal processing blocks 72-84 of audio amplifier 70. Alternatively, since the separated sub-frames 1,1 through 1,s occur within the same time period, the control parameters 1,k can be an average or other combination of the control parameters determined for each separated sub-frames 1,1 through 1,s.

The time domain and frequency domain parameters 1-j for separated sub-frame 2,1 in runtime matrix 174 and the parameters 1-j in each frame signatures 1-i are compared on a one-by-one basis and the weighted differences are recorded. For each parameter 1-j of separated sub-frame 2,1, compare block 242 determines the weighted difference between the parameter value in runtime matrix 174 and the parameter value in frame signature by weight i,j and stores the weighted difference in recognition memory 244. The weighted differences between the parameters 1-j of separated sub-frame 2,1 and the parameters 1-j of frame signature i are summed to determine a total weighted difference value between the parameters 1-j of separated sub-frame 2,1 and the parameters 1-j of frame signature i. The minimum total weighted difference between the parameters 1-j of separated sub-frame 2,1 of runtime matrix 174 and the parameters 1-j of frame signatures 1-i is the best match or closest correlation. The separated sub-frame 2,1 of runtime matrix 174 is identified with the frame signature having the minimum total weighted difference between corresponding parameters. Adaptive intelligence control block 94 uses the control parameters 1-k in database 92 associated with the matching frame signature to control operation of the signal processing blocks 72-84 of audio amplifier 70.

The control parameters 1,k of sub-frames 2,1 through 2,s each control different functions within signal processing blocks 72-84 of audio amplifier 70. Alternatively, since the separated sub-frames 2,1 through 2,s occur within the same time period, the control parameters 1,k can be an average or other combination of the control parameters determined for each separated sub-frames 2,1 through 2,s. The process continues for each separated sub-frame n,s of runtime matrix 174.

In another embodiment, a probability of correlation between corresponding parameters in runtime matrix 174 and frame signatures 1-i is determined. In other words, a probability of correlation is determined as a percentage that a given parameter in runtime matrix 174 is likely the same as the corresponding parameter in frame signature i. The percentage is a likelihood of a match. As described above, the time domain parameters and frequency domain parameters in runtime matrix 174 are stored on a frame-by-frame basis. For each separated sub-frame n,s of each parameter j in runtime matrix 174 is represented by Pn,j=[Pn1, Pn2, . . . Pnj].

A probability ranked list R is determined between each separated sub-frame n,s of each parameter j in runtime matrix 174 and each parameter j of each frame signature i. The probability value rᵢ can be determined by a root mean square analysis for the Pn,j and frame signature database Si,j in equation (4):

$${r}_{i} = \sqrt{\frac{{( {P}_{n1} - {S}_{i1} )}^{2} + {( {P}_{n2} - {S}_{i2} )}^{2} + ⋯ {( {P}_{nj} - {S}_{ij} )}^{2}}{j}} \qquad ( 4 )$$

The probability value R is (1−rᵢ)×100%. The overall ranking value for Pn,j and note database S_{i,j} is given in equation (5).

R=[(1−r₁)×100%(1−r₂)×100%(1−rᵢ)×100%] (5)

In some cases, the matching process identifies two or more frame signatures that are close to the present frame. For example, a frame in runtime matrix 174 may have a 52% probability that it matches to frame signature 1 and a 48% probability that it matches to frame signature 2. In this case, an interpolation is performed between the control parameter 1,1, control parameter 1,2 through control parameter 1,k and control parameter 2,1, control parameter 2,2, through control parameter 2,k, weighted by the probability of the match. The net effective control parameter 1 is 0.52*control parameter 1,1+0.48*control parameter 2,1. The net effective control parameter 2 is 0.52*control parameter 1,2+0.48*control parameter 2,2. The net effective control parameter k is 0.52*control parameter 1,k+0.48*control parameter 2,k. The net effective control parameters 1-k control operation of the signal processing blocks 72-84 of audio amplifier 70. The audio signal is processed through pre-filter block 72, pre-effects block 74, non-linear effects block 76, user-defined modules 78, post-effects block 80, post-filter block 82, and power amplification block 84, each operating as set by net effective control parameters 1-k, respectively. The audio signal is routed to speakers 46 in automobile 24. The listener hears the reproduced audio signal enhanced in realtime with characteristics determined by the dynamic content of the audio signal.

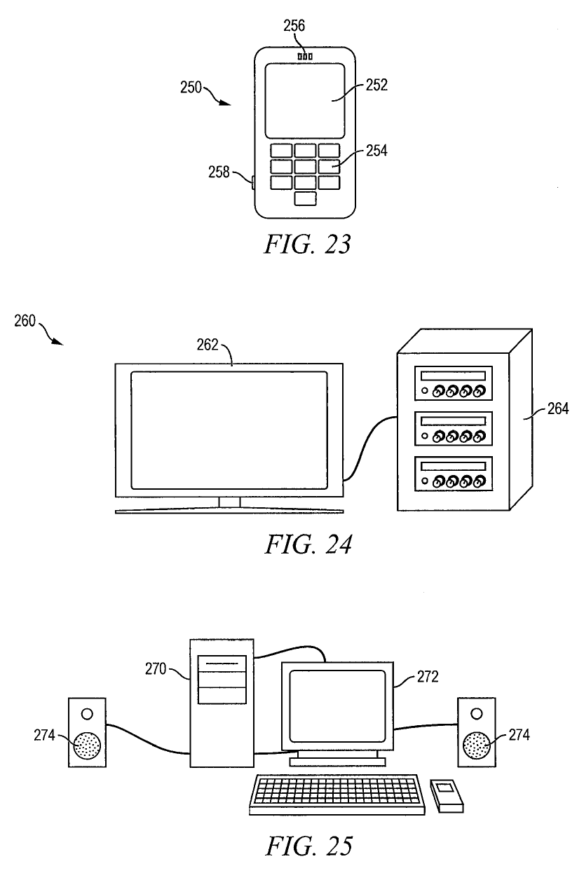

The signal processing functions can be associated with equipment other than automobile sound system 20. FIG. 23 shows a cellular phone 250 with display 252 and keypad 254. A musical composition or audio/video (AV) data can be stored within the memory of cellular phone 250 for later playback. Alternatively, the musical composition or AV data can be transmitted to cellular phone 250 over its wireless communication link. When the user selects the musical composition or AV data, an audio signal is generated from the stored or transmitted musical composition or AV data. Cellular phone 250 includes electronics, such as central processing unit (CPU) or digital signal processor (DSP) and software, that performs the signal processing functions on the audio signal associated with the musical composition or AV data. The signal processing function can be implemented as shown in FIG. 6. The signal conditioned audio signal is routed to speaker 256 or audio jack 258, which is adapted for receiving a headphones plug-in, to reproduce the sound content of the musical composition or AV data with the enhancements introduced into the audio signal by cellular phone 250.

To accommodate the signal processing requirements for the dynamic content of the audio source, cellular phone 250 employs a dynamic adaptive intelligence feature involving frequency domain analysis and time domain analysis of the audio signal on a frame-by-frame basis and automatically and adaptively controls operation of the signal processing functions and settings within the cellular phone to achieve an optimal sound reproduction, see blocks 90-94 of FIG. 6. Each incoming separated sub-frame of the audio signal is detected and analyzed to determine its time domain and frequency domain content and characteristics, as described in FIGS. 6-19. The incoming separated sub-frame is compared to a database of established or learned frame signatures to determine a best match or closest correlation of the incoming frame to the database of frame signatures, as described in FIGS. 20-22. The best matching frame signature from the database contains the control configuration of signal processing function, see blocks 72-84 of FIG. 6. The best matching frame signature controls operation of signal processing blocks in realtime on a frame-by-frame basis to continuously and automatically make adjustments to the signal processing functions for an optimal sound reproduction.

FIG. 24 shows a home entertainment system 260 with video display 262 and audio equipment rack 264. A musical composition or AV data can be stored within a memory component, e.g., CD or DVD, of audio equipment rack 264 for later playback. Alternatively, the musical composition or AV data can be transmitted to home entertainment system 260 over its cable or satellite link. When the user selects the musical composition or AV data, an audio signal is generated from the stored or transmitted musical composition or AV data. Audio equipment rack 262 includes electronics that performs the signal processing functions on the audio signal associated with the musical composition or AV data. The signal processing function can be implemented as shown in FIG. 6. The signal conditioned audio signal is routed to speaker 266 to reproduce the sound content of the musical composition or AV data with the enhancements introduced into the audio signal by audio equipment rack 262.

To accommodate the signal processing requirements for the dynamic content of the audio source, audio equipment rack 262 employs a dynamic adaptive intelligence feature involving frequency domain analysis and time domain analysis of the audio signal on a frame-by-frame basis and automatically and adaptively controls operation of the signal processing functions and settings within the cellular phone to achieve an optimal sound reproduction, see blocks 90-94 of FIG. 6. Each incoming separated sub-frame of the audio signal is detected and analyzed to determine its time domain and frequency domain content and characteristics, as described in FIGS. 6-19. The incoming separated sub-frame is compared to a database of established or learned frame signatures to determine a best match or closest correlation of the incoming frame to the database of frame signatures, as described in FIGS. 20-22. The best matching frame signature from the database contains the control configuration of signal processing function, see blocks 72-84 of FIG. 6. The best matching frame signature controls operation of signal processing blocks in realtime on a frame-by-frame basis to continuously and automatically make adjustments to the signal processing functions for an optimal sound reproduction.

FIG. 25 shows a computer 270 with video display 272. A musical composition or audio/video (AV) data can be stored within the memory of computer 270 for later playback. Alternatively, the musical composition or AV data can be transmitted to computer 270 over its wired or wireless communication link. When the user selects the musical composition or AV data, an audio signal is generated from the stored or transmitted musical composition or AV data. Computer 270 includes electronics, such as CPU or DSP and software, that performs the signal processing functions on the audio signal associated with the musical composition or AV data. The signal processing function can be implemented as shown in FIG. 6. The signal conditioned audio signal is routed to speaker 274 or audio jack 276, which is adapted for receiving a headphones plug-in, to reproduce the sound content of the musical composition or AV data with the enhancements introduced into the audio signal by computer 270.

To accommodate the signal processing requirements for the dynamic content of the audio source, computer 270 employs a dynamic adaptive intelligence feature involving frequency domain analysis and time domain analysis of the audio signal on a frame-by-frame basis and automatically and adaptively controls operation of the signal processing functions and settings within the cellular phone to achieve an optimal sound reproduction, see blocks 90-94 of FIG. 6. Each incoming separated sub-frame of the audio signal is detected and analyzed to determine its time domain and frequency domain content and characteristics, as described in FIGS. 6-19. The incoming, separated sub-frame is compared to a database of established or learned frame signatures to determine a best match or closest correlation of the incoming frame to the database of frame signatures, as described in FIGS. 20-22. The best matching frame signature from the database contains the control configuration of signal processing function, see blocks 72-84 of FIG. 6. The best matching frame signature controls operation of signal processing blocks in realtime on a frame-by-frame basis to continuously and automatically make adjustments to the signal processing functions for an optimal sound reproduction.

While one or more embodiments of the present invention have been illustrated in detail, the skilled artisan will appreciate that modifications and adaptations to those embodiments may be made without departing from the scope of the present invention as set forth in the following claims.

What is claimed is:

1. A consumer audio system, comprising a signal processor coupled for receiving an audio signal from a consumer audio source, wherein dynamic content of the audio signal controls operation of the signal processor.

2. The consumer audio system of claim 1, further including:
a time domain processor coupled for receiving the audio signal and generating time domain parameters of the audio signal;
a frequency domain processor coupled for receiving the audio signal and generating frequency domain parameters of the audio signal;
a signature database including a plurality of signature records each having time domain parameters and frequency domain parameters and control parameters; and
a recognition detector for matching the time domain parameters and frequency domain parameters of the audio signal to a signature record of the signature database, wherein the control parameters of the matching signature record control operation of the signal processor.

3. The consumer audio system of claim 2, wherein the time domain processor or frequency domain processor detects onset of a note of the audio signal.

4. The consumer audio system of claim 2, wherein the time domain parameters include a beat detector, loudness detector, and note temporal.

5. The consumer audio system of claim 2, wherein the frequency domain parameters include a pitch detector, note spectral, note partial, note inharmonicity, attack frequency, and harmonic derivative.

6. The consumer audio system of claim 1, wherein the signal processor includes a pre-filter, pre-effects, non-linear effects, user-defined module, post-effects, post-filter, or power amplification.

7. The consumer audio system of claim 1, wherein the audio signal is sampled into a plurality of frames of the sampled audio signal.

8. The consumer audio system of claim 1, wherein the sampled audio signal is separated into sub-frames.

9. The audio system of claim 1, wherein the audio signal is generated by an instrument, vocals, computer, or electronic device.

10. A method of controlling a consumer audio system, comprising:
providing a signal processor adapted for receiving an audio signal from a consumer audio source; and
controlling operation of the signal processor using dynamic content of the audio signal.

11. The method of claim 10, further including:
generating time domain parameters of the audio signal;
generating frequency domain parameters of the audio signal;
providing a signature database including a plurality of signature records each having time domain parameters and frequency domain parameters and control parameters;
matching the time domain parameters and frequency domain parameters of the audio signal to a signature record of the signature database; and
controlling operation of the signal processor based on the control parameters of the matching signature record.

12. The method of claim 11, further including:
sampling the audio signal into a plurality of frames;
separating the sampled audio signal into sub-frames; and
generating the time domain parameters and frequency domain parameters based on the separated sub-frames.

13. The method of claim 11, wherein the time domain processor or frequency domain processor detects onset of a note of the audio signal.

14. The method of claim 11, wherein the time domain parameters include a beat detector, loudness detector, and note temporal.

15. The method of claim 11, wherein the frequency domain parameters include a pitch detector, note spectral, note partial, note inharmonicity, attack frequency, and harmonic derivative.

16. The method of claim 10, wherein the signal processor includes a pre-filter, pre-effects, non-linear effects, user-defined module, post-effects, post-filter, or power amplification.

17. The method of claim 10, further including generating the audio signal with an instrument, vocals, computer, or electronic device.

18. A consumer audio system, comprising:
a signal processor coupled for receiving an audio signal from a consumer audio source;
a time domain processor coupled for receiving the audio signal and generating time domain parameters of the audio signal;
a frequency domain processor coupled for receiving the audio signal and generating frequency domain parameters of the audio signal;
a signature database including a plurality of signature records each having time domain parameters and frequency domain parameters and control parameters; and
a recognition detector for matching the time domain parameters and frequency domain parameters of the audio signal to a signature record of the signature database, wherein the control parameters of the matching signature record control operation of the signal processor.

19. The consumer audio system of claim 18, wherein the signal processor includes a pre-filter, pre-effects, non-linear effects, user-defined module, post-effects, post-filter, or power amplification.

20. The consumer audio system of claim 18, wherein the audio signal is sampled into a plurality of frames of the sampled audio signal.

21. The consumer audio system of claim 18, wherein the sampled audio signal is separated into sub-frames.

22. The consumer audio system of claim 18, wherein the time domain parameters include a beat detector, loudness detector, and note temporal, and the frequency domain parameters include a pitch detector, note spectral, note partial, note inharmonicity, attack frequency, and harmonic derivative.

23. The consumer audio system of claim 18, wherein the signal processor includes a pre-filter, pre-effects, non-linear effects, user-defined module, post-effects, post-filter, or power amplification.

24. The consumer audio system of claim 18, wherein the audio signal is generated by an instrument, vocals, computer, or electronic device.

25. A method of controlling a consumer audio system, comprising:
providing a signal processor adapted for receiving an audio signal from a consumer audio source;
generating time domain parameters of the audio signal;
generating frequency domain parameters of the audio signal;
providing a signature database including a plurality of signature records each having time domain parameters and frequency domain parameters and control parameters;
matching the time domain parameters and frequency domain parameters of the audio signal to a signature record of the signature database; and
controlling operation of the signal processor based on the control parameters of the matching signature record.

26. The method of claim 25, wherein the signal processor includes a pre-filter, pre-effects, non-linear effects, user-defined module, post-effects, post-filter, or power amplification.

27. The method of claim 25, further including:
sampling the audio signal; and
separating the sampled audio signal into sub-frames; and
generating the time domain parameters and frequency domain parameters based on the separated sub-frames.

28. The method of claim 25, further including detecting an onset of a note of the audio signal.

29. The method of claim 25, wherein the time domain parameters include a beat detector, loudness detector, and note temporal.

30. The method of claim 25, wherein the frequency domain parameters include a pitch detector, note spectral, note partial, note inharmonicity, attack frequency, and harmonic derivative.

31. The method of claim 25, further including generating the audio signal with an instrument, vocals, computer, or electronic device.
